(19) United States
(12) Patent Application Publication
(10) Pub. No.: US 2025/0174254 A1
(43) Pub. Date: May 29, 2025

(54) SHIFT CIRCUIT, MEMORY CONTROLLER, AND MEMORY SYSTEM

(71) Applicant: YANGTZE MEMORY TECHNOLOGIES CO., LTD., Wuhan (CN)

(72) Inventors: Zhiwei ZHUANG, Wuhan (CN); Dili WANG, Wuhan (CN)

(21) Appl. No.: 18/746,718

(22) Filed: Jun. 18, 2024

(30) Foreign Application Priority Data
Nov. 27, 2023 (CN) 2023116147132

(51) Int. Cl. G11C 7/10; G11C 29/52

(52) U.S. Cl. CPC G11C 7/1036; G11C 7/1012; G11C 29/52

(57) ABSTRACT

Examples of the present disclosure disclose a shift circuit, a data selector, a memory controller, and a memory system. The shift circuit includes: a data selector, including a first input terminal, a second input terminal, a third input terminal, a fourth input terminal, and an output terminal, wherein the first input terminal is configured to access a first control signal, the third input terminal is configured to access a second control signal, the first control signal and the second control signal are inverse signals to each other, the fourth input terminal is configured to access a corresponding first bit in input data, and the second input terminal is configured to access a corresponding second bit in the input data; and when the first control signal is in a first state, the output terminal outputs an inverted value of the second bit.

### CROSS-REFERENCE TO RELATED APPLICATIONS

This application claims the benefit of priority to China Patent Application No. CN 2023116147132, filed on Nov. 27, 2023, which is incorporated herein by reference in its entirety.

### TECHNICAL FIELD

The present disclosure relate to the technical field of semiconductor technology, and particularly to a shift circuit, a data selector, a memory controller, and a memory system.

### BACKGROUND

A memory device is a storage apparatus used to save information in modern information technologies. As a typical nonvolatile semiconductor memory, a Not-And (NAND) type memory gradually becomes a mainstream product in the memory market due to a relatively high memory density, controllable production costs, appropriate program and erase speed, and a retention characteristic.

However, with the increasingly high requirements for the storage apparatus, there is still much room for improvements in the memory device and a system thereof.

### SUMMARY

According to some aspects of examples of the present disclosure, a shift circuit is provided, comprising:
a data selector, comprising a first input terminal, a second input terminal, a third input terminal, a fourth input terminal, and an output terminal, wherein
the first input terminal is configured to access a first control signal, the third input terminal is configured to access a second control signal, and the first control signal and the second control signal are inverse signals to each other,
the fourth input terminal is configured to access a corresponding first bit in input data,
the second input terminal is configured to access a corresponding second bit in the input data, and
when the first control signal is in a first state, the output terminal outputs an inverted value of the second bit; or/and
when the first control signal is in a second state, the output terminal outputs an inverted value of the first bit.

In some examples, the shift circuit comprises a plurality of data selectors, wherein the second input terminal of the data selector is configured to access a corresponding second bit of the input data after being shifted by 2ⁱ bits, wherein i comprises any integer greater than or equal to 0.

In some examples, the shift circuit comprises:
n levels of sub-shift circuits, wherein each of the sub-shift circuits comprises the plurality of data selectors and is configured to: receive the input data, and shift the input data by 2ⁱ bits, wherein the input data comprises output data of a previous level of sub-shift circuit or original input data, and a value of i of any level of sub-shift circuit of the n levels of sub-shift circuits comprises any integer from 0 to n−1, wherein a value of n comprises any integer greater than or equal to 1.

In some examples, the sub-shift circuit is configured to:
receive the input data, and shift the input data by 2ⁱ bits under control of one bit in a shift factor, wherein a bit in the shift factor is to generate a first control signal and a second control signal for a corresponding level.

In some examples, in a case that n is an even number, an output of a last level of sub-shift circuit of the n levels of sub-shift circuits is target data; and in a case that n is an odd number, an output of a last level of sub-shift circuit of the n levels of sub-shift circuits is inverted to obtain the target data.

In some examples, values of i in a first level of sub-shift circuit, a second level of sub-shift circuit, . . . , and an nth level of sub-shift circuit of the n levels of sub-shift circuits are respectively n−1, n−2, n−3, . . . , and 0, and a number of data selectors comprised in each level of sub-shift circuit is the same as a number of bits of the input data.

In some examples, the number of the plurality of data selectors of the shift circuit is equal to the number of bits of the input data multiplied by the number of levels.

In some examples, the shift circuit further comprises:
an inverter circuit coupled with the third input terminal, wherein the first input terminal and the inverter circuit are configured to access a high level, the first control signal at the high level is in the first state, and the third input terminal is configured to access a low level output by the inverter circuit; or
the first input terminal and the inverter circuit are configured to access a low level, the first control signal at the low level is in the second state, and the third input terminal is configured to access a high level output by the inverter circuit.

In some examples, the shift circuit further comprises:
an inverter circuit coupled with the first input terminal, wherein the inverter circuit and the third input terminal are configured to access a high level, the first input terminal is configured to access a low level output by the inverter circuit, and the first control signal at the low level is in the first state; or
the inverter circuit and the third input terminal are configured to access a low level, the first input terminal is configured to access a high level output by the inverter circuit, and the first control signal at the high level is in the second state

According to some aspects of examples of the present disclosure, a data selector is provided, comprising:
a first input terminal, a second input terminal, a third input terminal, a fourth input terminal, and an output terminal, wherein
the first input terminal is configured to access a first control signal, the third input terminal is configured to access a second control signal, the fourth input terminal is configured to access a first bit, the second input terminal is configured to access a second bit, and the first control signal and the second control signal are inverse signals to each other, and
when the first control signal is in a first state, the output terminal outputs an inverted value of the second bit; or
when the first control signal is in a second state, the output terminal outputs an inverted value of the first bit.

According to some aspects of examples of the present disclosure, a memory controller is provided, wherein the memory controller is configured to perform an encoding operation according to program data in response to a program operation to generate a check code,
the memory controller comprises a shift circuit, and the shift circuit comprises:
a data selector, comprising a first input terminal, a second input terminal, a third input terminal, a fourth input terminal, and an output terminal, wherein the first input terminal is configured to access a first control signal, the third input terminal is configured to access a second control signal, the first control signal and the second control signal are inverse signals to each other, the fourth input terminal is configured to access a corresponding first bit in input data, and the second input terminal is configured to access a corresponding second bit in the input data, and
when the first control signal is in a first state, the output terminal outputs an inverted value of the second bit; or when the first control signal is in a second state, the output terminal outputs an inverted value of the first bit, and
wherein the shift circuit is configured to output the inverted value of the second bit or the inverted value of the first bit in response to the encoding operation.

In some examples, the memory controller is further configured to:
perform a decoding operation according to the corresponding check code in response to a read error to readout data, wherein the shift circuit is configured to output the inverted value of the second bit or the inverted value of the first bit in response to the decoding operation.

In some examples, the shift circuit comprises a plurality of data selectors, and the second input terminal of the data selector is configured to access a corresponding second bit of the input data after being shifted by 2ⁱ bits, wherein i comprises any integer greater than or equal to 0.

In some examples, the shift circuit comprises:
n levels of sub-shift circuits, wherein each of the sub-shift circuits comprises the plurality of data selectors and is configured to: receive the input data, and shift the input data by 2ⁱ bits, wherein the input data comprises output data of a previous level of sub-shift circuit or original input data, and a value of i of any level of sub-shift circuit of the n levels of sub-shift circuits comprises any integer from 0 to n−1, wherein a value of n comprises any integer greater than or equal to 1.

In some examples, the sub-shift circuit is configured to:
receive the input data, and shift the input data by 2ⁱ bits under control of one bit in a shift factor, wherein a bit in the shift factor is to generate a first control signal and a second control signal for a corresponding level.

In some examples, in a case that n is an even number, an output of a last level of sub-shift circuit of the n levels of sub-shift circuits is target data; and in a case that n is an odd number, an output of a last level of sub-shift circuit of the n levels of sub-shift circuits is inverted to obtain the target data.

In some examples, values of i in a first level of sub-shift circuit, a second level of sub-shift circuit, . . . , and an nth level of sub-shift circuit of the n levels of sub-shift circuits are respectively n−1, n−2, n−3, . . . , and 0, and a number of data selectors comprised in each level of sub-shift circuit is the same as a number of bits of the input data.

In some examples, the number of the plurality of data selectors of the shift circuit is equal to the number of bits of the input data multiplied by the number of levels.

In some examples, the shift circuit further comprises:
an inverter circuit coupled with the third input terminal, wherein the first input terminal and the inverter circuit are configured to access a high level, the first control signal at the high level is in the first state, and the third input terminal is configured to access a low level output by the inverter circuit; or
the first input terminal and the inverter circuit are configured to access a low level, the first control signal at the low level is in the second state, and the third input terminal is configured to access a high level output by the inverter circuit.

In some examples, the shift circuit further comprises:
an inverter circuit coupled with the first input terminal, wherein the inverter circuit and the third input terminal are configured to access a high level, the first input terminal is configured to access a low level output by the inverter circuit, and the first control signal at the low level is in the first state; or
the inverter circuit and the third input terminal are configured to access a low level, the first input terminal is configured to access a high level output by the inverter circuit, and the first control signal at the high level is in the second state.

According to some aspects of examples of the present disclosure, a memory system is provided, comprising a memory device and the memory controller, wherein the memory controller is coupled with the memory device and configured to control the memory device.

The shift circuit provided in the examples of the present disclosure comprises a data selector, and data output of the data selector may be controlled by controlling a high and low level of the first control signal, facilitating the realization of multiple shift scenarios of the input data through logic control, facilitating the expansion of the adaptability of the shift circuit to a variety of integrated circuits, and facilitating the expansion of the adaptability of the shift circuit to a variety of data shift algorithms.

### BRIEF DESCRIPTION OF THE DRAWINGS

FIG. 1A is a schematic diagram illustrating a shift circuit formed by data selectors according to examples of the present disclosure;

FIG. 1B is a schematic diagram illustrating another shift circuit formed by data selectors according to examples of the present disclosure;

FIG. 2 is a schematic diagram illustrating an AOI data selector according to examples of the present disclosure;

FIG. 3 is a schematic diagram illustrating an OAI data selector according to examples of the present disclosure;

FIG. 4 is a schematic diagram illustrating a 4-to-1 data selector formed by AOI data selectors according to examples of the present disclosure;

FIGS. 5 to 9 are schematic diagrams illustrating a shift circuit that is formed based on a plurality of AOI data selectors and is configured to shift data along a first direction according to examples of the present disclosure;

FIG. 10 is a schematic diagram illustrating a shift circuit that is formed based on a plurality of AOI data selectors and is configured to shift data along a second direction according to examples of the present disclosure;

FIG. 11 is a schematic diagram illustrating a shift circuit that is formed based on a plurality of OAI data selectors and is configured to shift data along a first direction according to examples of the present disclosure;

FIG. 12 is a schematic diagram illustrating a shift circuit that is formed based on a plurality of AOI data selectors and is configured to shift data along a second direction according to examples of the present disclosure;

FIG. 13 is a schematic diagram illustrating an example system comprising a memory system according to examples of the present disclosure;

FIG. 14A is a schematic diagram illustrating an example memory card according to examples of the present disclosure;

FIG. 14B is a schematic diagram illustrating an example solid-state drive according to examples of the present disclosure;

FIG. 15 is a schematic diagram illustrating an example memory device according to examples of the present disclosure;

FIG. 16 is a schematic diagram illustrating a part of a memory cell array according to examples of the present disclosure;

FIG. 17 is a schematic block diagram illustrating an example memory device according to examples of the present disclosure;

FIG. 18 is a schematic flow diagram illustrating a read operation comprising a read retry operation according to examples of the present disclosure; and

FIG. 19 is a schematic block diagram illustrating an example application of a memory controller comprising an error correction module in a memory system according to examples of the present disclosure.

In the above drawings (which are not drawn to scale), like reference numerals may describe like parts in the different views. Like reference numbers with different letter suffixes may indicate different examples of like parts. The drawings illustrate the various examples discussed herein in general, by way of example and not limitation.

### DETAILED DESCRIPTION

Examples of the present disclosure will be described in more detail below with reference to the accompanying drawings. Although examples of the present disclosure are shown in the drawings, it should be understood that the present disclosure may be implemented in various ways and should not be limited to the DETAILED DESCRIPTION set forth herein. Rather, these examples are provided so that the present disclosure can be more thoroughly understood and the scope of the present disclosure can be fully conveyed to those skilled in the art.

In the following description, numerous specific details are given in order to provide a more thorough understanding of the present disclosure. It will be apparent, however, to one skilled in the art that the present disclosure may be practiced without one or more of these details. In other examples, some technical features well-known in the art are not described to avoid confusion with the present disclosure; that is, not all features of the actual example are described here, and well-known functions and structures are not described in detail.

It will be understood that when an element or layer is referred to as being “on,” “adjacent to,” “connected to” or “coupled to” other elements or layers, it can be directly on, adjacent to, connected to, or coupled to other elements or layers, or intervening elements or layers may be present. In contrast, when an element is referred to as being “directly on,” “directly adjacent to,” “directly connected to” or “directly coupled to” other elements or layers, there are no intervening elements or layers. It will be understood that, although the terms such as first, second, third etc. may be used to describe at least one of various elements, components, regions, layers or sections, at least one of these elements, components, regions, layers or sections should not be limited by these terms. These terms are only used to distinguish one element, component, region, layer or section from another element, component, region, layer or section. Thus, a first element, component, region, layer or section discussed below could be represented as a second element, component, region, layer or section without departing from the teachings of the present disclosure. When a second element, component, region, layer or section is discussed, it does not indicate that a first element, component, region, layer or section exists in the present disclosure.

Spatial relationship terms such as “under”, “below”, “beneath”, “underneath”, “on”, “above” and so on, can be used here for convenience to describe the relationship between one element or feature and other elements or features shown in the figures. It will be understood that the spatially relationship terms also comprise different orientations of the device in use and operation in addition to the orientation depicted in the figures. For example, if the device in the figures is turned over, elements or features described as “below” or “underneath” or “under” other elements or features would then be oriented as “above” the other elements or features. Thus, the example terms “below” and “under” can comprise both orientations of above and below. The device may be otherwise oriented (rotated 90 degrees or at other orientations) and the spatial descriptors used herein may be interpreted accordingly.

The terminology used herein is for the purpose of describing particular examples only and is not to be taken as a limitation of the present disclosure. As used herein, “a”, “an” and “said/the” in singular forms are intended to include the plural forms as well, unless the context clearly dictates otherwise. It should also be understood that at least one of the terms “consists of” or “comprising”, when used in this specification, identify the presence of at least one of stated features, integers, operations, elements or components, but do not exclude presence or addition of at least one of one or more other features, integers, operations, elements, components or groups. As used herein, the term “at least one of . . . ” includes any and all combinations of the associated listed items.

It is to be understood that, references to “some examples” or “an example” throughout this specification mean that particular features, structures, or characteristics related to the example are comprised in at least one example of the present disclosure. Therefore, “in some examples” or “in an example” presented everywhere throughout this specification does not necessarily refer to the same example. Furthermore, these particular features, structures, or characteristics may be incorporated in one or more examples in any suitable manner. It is to be understood that, in various examples of the present disclosure, sequence numbers of the above processes do not indicate an execution sequence, and the execution sequence of various processes shall be determined by functionalities and intrinsic logics thereof, and shall constitute no limitation on an implementation process of the examples of the present disclosure.

A shift circuit is widely used in various integrated circuits, and is configured to shift an input signal or input data. The shift circuit may usually have an input of m pieces of data and an output of m pieces of data. The m pieces of data are arranged in an order to form a data string before being input into the shift circuit, and the order of each piece of the data in the data string output after the operation of the shift circuit is changed or unchanged, and the two adjacent pieces of data may still be adjacent before and after output. Taking a data string data arrangement ABCDEFGH as an example, a number of bits of the data string is 8, the 1st bit of data is A, the 2nd bit of data is B, the 3rd bit of data is C, the 4th bit of data is D, the 5th bit of data is E, the 6th bit of data is F, the 7th bit of data is G, and the 8th bit of data is H. If the data of the data string is shifted to the right by 1 bit respectively, the original 1st bit of data A is shifted to the 2nd bit, the original 8th bit of data H is shifted to the 1st bit, and so on. For example, the 8-bit data ABCDEFGH is input into a shift circuit, the shift circuit can shift the data in the data string to the right by 1 bit respectively, and the data after shifting is arranged as HABCDEFG; the shift circuit can shift the data in the data string to the right by 2 bits respectively, and the data after shifting is arranged as GHABCDEF; the shift circuit can shift the data in the data string to the left by 1 bits respectively, and the data after shifting is arranged as BCDEFGHA; the shift circuit can shift the data in the data string to the left by 2 bits respectively, and the data after shifting is arranged as CDEFGHAB. It should be noted that the example data string consists of 8 bits of data, which can be shifted to the left or right by up to 7 bits, and shifting by 8 bits is equivalent to restoring the data arrangement before shifting, i.e., no data shifting. When the shift circuit shifts the data string by 0 bits, no data shift is performed. After the data is shifted by the shift circuit, the values of the data are not changed, and the data is output after only being shifted, or the original data value is inverted and output after the data is shifted. In some examples, after the 8 bits of data ABCDEFGH are shifted to the right by 1 bit, HABCDEFG may be output, or (˜H)(˜A)(˜B)(˜C)(˜D)(˜E)(˜F)(˜G) may be output. The example data string ABCDEFGH in this example is only an arrangement of data and does not represent a mathematical operational relationship between the data. In some examples, shifting to the right may refer to shifting in a first direction, and shifting to the left may refer to shifting in a second direction.

In some examples, the shift circuit may be formed by data selectors. The data selector may comprise a plurality of input terminals and one output terminal. At least one of the plurality of input terminals may be configured to input data to be shifted. The data to be shifted may comprise bits in this example, or may further comprise a data set or data packet with a larger data amount. The bit is only used as an example. At least one of the plurality of input terminals may further be configured to input a selection signal, and the output terminal is configured to output shifted data or unshifted data, or may be configured to output an inverted value of shifted data. The function of the data selector is to select and output a certain bit input by the data selector. When input terminals of a plurality of data selectors are coupled, bits input by two data selectors may be swapped, thereby achieving a shift of input bits. In a process of data swapping, the original bit after swapping can be output, or the original bit after swapping can be inverted and output.

The shift circuit may comprise one level of circuit, or may comprise a plurality of levels of sub-shift circuits. For example, the shift circuit may comprise n levels of sub-shift circuits. Each level of sub-shift circuit comprises a data selector with a bit width same as a bit width m of the input data. The data bit width here may be the number of bits of data of the data string ABCDEFGH in the foregoing example. The data bit width of ABCDEFGH is 8 bits. Each level of sub-shift circuit may shift the input data by any number of bits from 0 to m−1, and may shift the data to the left or to the right. A previous level of sub-shift circuit outputs shifted bits or unshifted bits, or outputs an inverted value of shifted bits or unshifted bits. The previous level of sub-shift circuit outputs data to a following level of sub-shift circuit, and an output value of a last level of sub-shift circuit is an output value of the entire shift circuit.

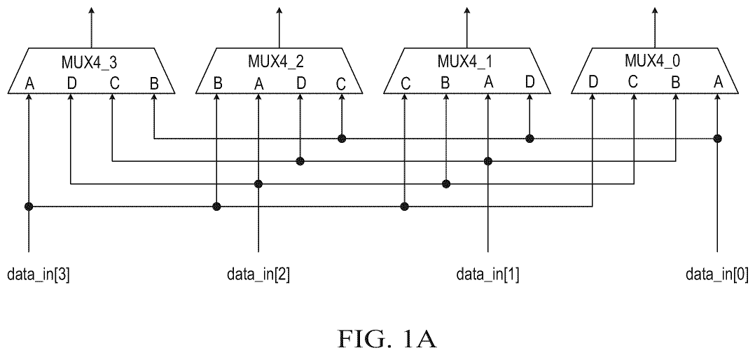

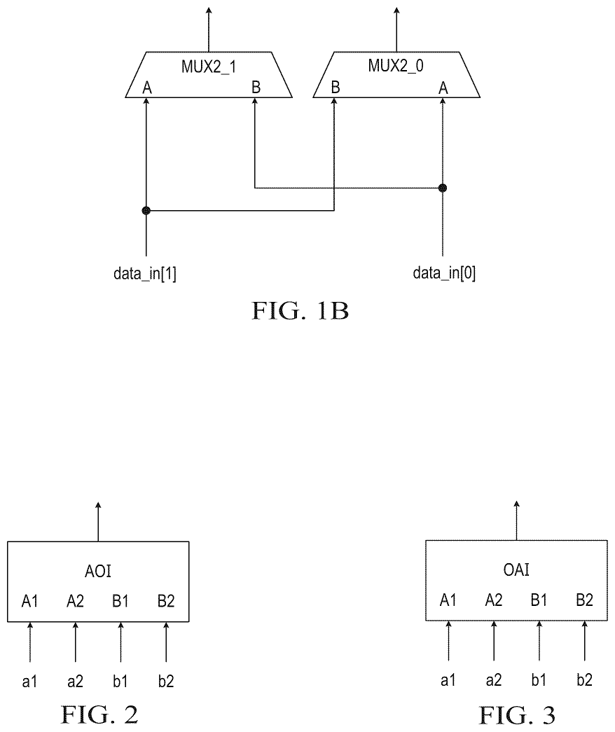

FIG. 1A illustrates an example shift circuit according to examples of the present disclosure. With reference to FIG. 1A, for example, the shift circuit is formed by 4 data selectors, and is configured to shift 4 input bits. Data corresponding to the input bits may comprise data_in[3], data_in[2], data_in[1], and data_in[0]. Each data selector has 4 input terminals and one output terminal, and the data selector may be a 4-to-1 data selector, and denoted as MUX4, which are respectively MUX4_3, MUX4_2, MUX4_1, and MUX4_0. data_in[3] is configured to access an input terminal A of MUX4_3, an input terminal B of MUX4_2, an input terminal C of MUX4_1, and an input terminal D of MUX4_0; data_in[2] is configured to access an input terminal D of MUX4_3, an input terminal A of MUX4_2, an input terminal B of MUX4_1, and an input terminal C of MUX4_0; data_in[1] is configured to access an input terminal C of MUX4_3, an input terminal D of MUX4_2, an input terminal A of MUX4_1, and an input terminal B of MUX4_0; and data_in[0] is configured to access an input terminal B of MUX4_3, an input terminal C of MUX4_2, an input terminal D of MUX4_1, and an input terminal A of MUX4_0. When the shift circuit shifts the original input data data_in[3], data_in[2], data_in[1], and data_in[0] by 0 bits, MUX4_3, MUX4_2, MUX4_1, and MUX4_0 output the signals input all from the input terminals A after an internal data selection operation, and output data_in[3], data_in[2], data_in[1], and data_in[0] respectively. When the shift circuit shifts the original data to the right by 1 bit or to the left by 3 bits, each of the data selectors outputs signals input from the input terminals B, and output data_in[0], data_in[3], data_in[2], and data_in[1] respectively. When the shift circuit shifts the original data to the right by 2 bits or to the left by 2 bits, each of the data selectors outputs signals input from the input terminals C, and output data_in[1], data_in[0], data_in[3], and data_in[2] respectively. When the shift circuit shifts the original data to the right by 3 bits or to the left by 1 bit, each of the data selectors output signals input from the input terminals D, and output data_in[2], data_in[1], data_in[0], and data_in[3] respectively. The signals output by the data selector MUX4 in the example may be achieved through an internal logical circuit of the data selector MUX4 in combination with actual program settings. For data with a larger number of bits, for example, data_in[0] to data_in[m], m corresponding MUX4 data selectors are required. For a shift circuit formed by a plurality of levels of sub-shift circuits, the number of data selectors MUX4 of each level is m. The number of possibilities for each level of sub-shift circuit to shift data to the left may be 4, and the number of possibilities for each level of sub-shift circuit to shift data to the right may be 4, which may be set according to the number of shifts of the actual data. The data selectors MUX4_0 to MUX4_4 are data selectors with a same data selection function. The serial numbers are only used for literal distinguishing to facilitate description.

In some examples, the MUX4 data selectors in FIG. 1A have relatively complex internal circuits. The circuit area of one MUX4 data selector is relatively large, and one MUX4 data selector may be replaced by two 2-to-1 data selectors (MUX2 data selectors), i.e., two MUX2 data selectors may be equivalent to one MUX4 data selector. With reference to an example in FIG. 1B, two MUX2 data selectors form a basic shift circuit for shifting two-bit data. The MUX2 data selector may comprise two input terminals, namely, an input terminal A and an input terminal B. data_in[0] is configured to access the input terminal A of MUX2_0 and the input terminal B of MUX2_1. data_in[1] is configured to access the input terminal A of MUX2_1 and the input terminal B of MUX2_0. When the shift circuit shifts original input data data_in[1] and data_in[0] by 0 bits, each of the MUX2 data selectors outputs signals input from the input terminals A, and output data_in[1] and data_in[0] respectively. When the shift circuit shifts the data to the right by 1 bit or to the left by 1 bit, each of the MUX2 data selectors outputs signals input from the input terminals B, and output data_in[0] and data_in[1] respectively.

In an example, with reference to a MUX4 data selector, the circuit area of a MUX2 data selector is 40% of the circuit area of a MUX4 data selector, and the total area of the two MUX2 data selectors is less than the area of a MUX4 data selector. In the example, two MUX2 data selectors may be used in place of one MUX4 to build the shift circuit, so that a circuit area of the shift circuit is reduced, which helps to improve a level of integration of the integrated circuit.

In some examples, with reference to FIG. 2, an And-Or-Invert (AOI) data selector is provided. Different from the MUX4 data selectors and the MUX2 data selectors in FIG. 1A, in addition to original data to be shifted, a control signal or an enable signal may be further input at an input terminal of the AOI data selector. A logical calculation is performed on the control signal and the original data to output the original data input or shifted data, or an inverted value of the original data or the shifted data may be output. In an example in FIG. 2, the AOI data selector comprises four input terminals, which may be denoted as a first input terminal A1, a second input terminal A2, a third input terminal B1, a fourth input terminal B2, and one output terminal. A logical calculation performed on input signals at the four input terminals by the AOI data selector is !((A1&A2)+(B1&B2)), wherein & represents an AND operation, + represents an OR operation, and ! represents a NOT operation (inversion operation). In an example, logical signals input at the input terminals A1, A2, B1, and B2 are respectively a1, a2, b1, and b2, and the logical calculation is !((a1&a2)+(b1&b2)). When a1=1 and b1=0, an inverted value −a2 of data at the input terminal A2 is output. When a1=0 and b1=1, an inverted value −b2 of data at the B2 input terminal is output. In the example, when the signal is at a high level, a value of 1 is assigned, and when the signal is at a low level, a value of 0 is assigned. a1 and b1 are not output at a final output terminal, and only a2 or b2 is output. a1 and b1 may be used as control signals of the AOI data selector, wherein a1 may be a first control signal, and b1 may be a second control signal. One of ˜a2 and ˜b2 is used as a signal selected for output. The AOI data selector may be considered as a 2-to-1 data selector having two control signals with opposite levels. The AOI data selector may be configured to build a shift circuit. Through high and low levels of the first control signal accessed at the first input terminal A1 or through high and low levels of the second control signal accessed at the third input terminal B1, it is selected to output an inverted value of data input at the second input terminal A2 or it is selected to output an inverted value of data input at the fourth input terminal B2, so that the data is shifted or not shifted.

In some examples, FIG. 3 provides an Or-And-Invert (OAI) data selector, which is similar to the AOI data selector. The OAI data selector has 4 input signals, two of which are used as control signals and are not output, and one of the two pieces of input data that are not control signals is selected, and the selected data is inverted and output. With reference to FIG. 3, the OAI data selector comprises four input terminals, which may be denoted as a first input terminal A1, a second input terminal A2, a third input terminal B1, a fourth input terminal B2, and one output terminal. A logical calculation performed on input signals at the four input terminals by the OAI data selector is !((A1+A2)&(B1+B2)), wherein & represents an AND operation, + represents an OR operation, and ! represents a NOT operation (inversion operation). In an example, logical signals input at the input terminals A1, A2, B1, and B2 are respectively a1, a2, b1, and b2, and the logical calculation is !((a1+a2)&(b1+b2)). When a1=0 and b1=1, an inverted value-a2 of data at the input terminal A2 is output. When a1=1 and b1=0, an inverted value-b2 of data at the B2 input terminal is output. In the example, when the signal is at a high level, a value of 1 is assigned, and when the signal is at a low level, a value of 0 is assigned. a1 and b1 are not output at a final output terminal, and only ˜a2 or ˜b2 is output. a1 and b1 may be used as control signals of the OAI data selector, wherein a1 may be a first control signal, and b1 may be a second control signal. One of ˜a2 and ˜b2 is used as a signal selected for output. The OAI data selector may be considered as a 2-to-1 data selector having two control signals with opposite levels. The OAI data selector may be configured to build a shift circuit. Through high and low levels of the first control signal accessed at the first input terminal A1 or through high and low levels of the second control signal accessed at the third input terminal B1, it is selected to output an inverted value of data input at the second input terminal A2 or it is selected to output an inverted value of data input at the fourth input terminal B2, so that the data is shifted or not shifted.

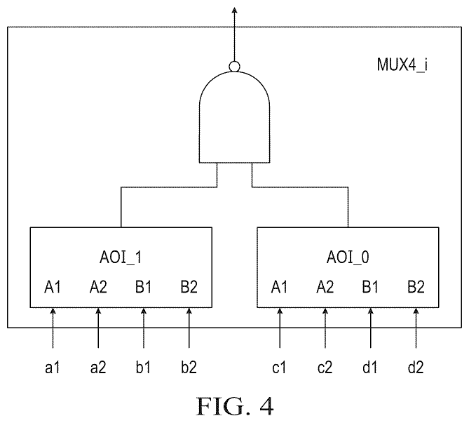

In some examples, two AOI data selectors may form one 4-to-1 data selector. For example, output terminals of the two AOI data selectors are connected to a gate circuit having two input terminals and one output terminal to form a 4-to-1 data selector. With reference to an example in FIG. 4, two AOI data selectors AOI_0 and AOI_1 and one AND gate (ND2) form a data selector MUX4_i. The two AOI data selectors output data to the AND gate (ND2). The AND gate ND2 outputs final data. Data input at input terminals A1, A2, B1, and B2 of AOI_1 are respectively a1, a2, b1, and b2. Data input at input terminals A1, A2, B1, and B2 of AOI_0 are respectively c1, c2, d1, and d2. A logical operation performed by the MUX4 data selector is ! ((!((a1&a2)+(b1&b2)))&(!((c1&c2)+(d1&d2)))). When a1=1, b1=0, c1=0, and d1=0, a2 is output. When a1=0, b1=1, c1=0, and d1=0, b2 is output. When a1=0, b1=0, c1=1, and d1=0, c2 is output. When a1=0, b1=0, c1=0, and d1=1, d2 is output. There are 4 cases of data selection. In some other examples, the AOI data selector in FIG. 4 may be placed with the OAI data selector to form another data selector MUX4_i. Output terminals of the two OAI data selectors are connected to the AND gate ND2, and an output terminal of ND2 outputs data. In some examples, the data selector MUX4_i may be equivalent to one MUX4_0, which is equivalent to two MUX_0.

In some examples, a circuit area of the AOI data selector and a circuit area of the OAI data selector may be equal or substantially equal within a certain error range. Taking the AOI data selector as an example, the circuit area of the AOI data selector is 25% of a circuit area of the MUX4 data selector (for example, MUX4_0) in FIG. 1A, the circuit area of the AOI data selector is 62.5% of a circuit area of MUX2_0 in FIG. 1B, and a circuit area of the AND gate ND2 is 15% of the circuit area of the data selector MUX4_0. A total circuit area of the data selector MUX4_i in FIG. 4 is 65% of the circuit area of MUX4_0, and is 81.25% of a circuit area of two MUX2_0. For selection of 4-bit data, the circuit area of the data selector MUX4_i formed by the AOI data selector or the OAI data selector in the examples of the present disclosure is smaller than the circuit area of the data selector MUX4_0 and is smaller than the circuit area of two MUX2_0. For selection of two-bit data, the circuit area of the AOI data selector or the OAI data selector is smaller than the circuit area of the circuit selector MUX2_0.

In some examples, for a shift circuit formed by a plurality of data selectors, a shift circuit formed by a plurality of AOI data selectors or a plurality of OAI data selectors has a smaller circuit area compared with a shift circuit formed by a plurality of data selectors MUX2_0, and also has a smaller circuit area compared with a shift circuit formed by a plurality of data selectors MUX4_0. In an example, for data with a bit width of 256 bits and a shift with a shift bit width of 8 bits, a data selector MUX4_0 may be used to build a shift circuit. The shift circuit is divided into 4 levels of sub-shift circuits, a shift bit width of each level of sub-shift circuit is 2 bits, and each level of sub-shift circuit has 4 shift cases. Therefore, each level of sub-shift circuit requires 256 data selectors MUX4_0, and the 4 levels of sub-shift circuits require a total of 256*4 data selectors MUX4_0. To achieve a shift circuit with a data bit width and a shift bit width being the same, data selectors MUX2_0 may be used to build 8 levels of sub-shift circuits to form a shift circuit, wherein a shift bit width of each level of shift circuit is 1 bit, and each level of sub-shift circuit has 2 shift cases. Therefore, each sub-shift circuit requires 256 data selectors MUX2_0, and the 8 levels of sub-shift circuits require a total of 256*8 data selectors MUX2_0, which enables a smaller circuit area compared with 256*4 data selectors MUX4_0. To achieve a shift circuit with a data bit width and a shift bit width being the same, AOI data selectors or OAI data selectors may be used to build a shift circuit. Taking the AOI data selector as an example. 8 levels of sub-shift circuits may be built to form a shift circuit, wherein a shift bit width of each level of sub-shift circuit is 1 bit, and each level of sub-shift circuit has 2 shift cases. Therefore, each sub-shift circuit requires 256 AOI data selectors, and the 8 levels of sub-shift circuits requires a total of 256*8 AOI data selectors, which enables a smaller circuit area compared with 256*8 data selectors MUX2_0 and a smaller circuit area compared with 256*4 data selectors MUX4_0.

In view of this, according to some aspects of the examples of the present disclosure, a shift circuit is provided and comprises: a data selector, comprising a first input terminal A1 (terminal A1), a second input terminal A2 (terminal A2), a third input terminal B1 (terminal B1), a fourth input terminal B2 (terminal B2), and an output terminal, wherein the first input terminal A1 is configured to access a first control signal, the third input terminal B1 is configured to access a second control signal, the first control signal and the second control signal are inverse signals to each other, the fourth input terminal B2 is configured to access a corresponding first bit in input data, and the second input terminal A2 is configured to access a corresponding second bit in the input data, and when the first control signal is in a first state, the output terminal outputs an inverted value of the second bit; or when the first control signal is in a second state, the output terminal outputs an inverted value of the first bit.

The shift circuit in the examples of the present disclosure may be formed by AOI data selectors or OAI data selectors, and may comprise one level of circuit, or may comprise a plurality of levels of sub-shift circuits. In the case that the shift circuit is formed by the AOI data selectors shown in FIG. 2, when a first control signal accessed at the terminal A1 is at a high level, a second control signal accessed at the terminal B1 is at a low level, the output terminal outputs an inverted value of a second bit accessed at the terminal A2. When the first control signal accessed at the terminal A1 is at a low level, the second control signal accessed at the terminal B1 is at a high level, the output terminal outputs an inverted value of a first bit accessed at the terminal B2. Alternatively, in the case that the shift circuit is formed by the OAI data selectors shown in FIG. 3, when a first control signal accessed at the terminal A1 is at a low level, a second control signal accessed at the terminal B1 is at a high level, the output terminal outputs an inverted value of a second bit accessed at the terminal A2. When the first control signal accessed at the terminal A1 is at a high level, the second control signal accessed at the terminal B1 is at a low level, the output terminal outputs an inverted value of a first bit accessed at the terminal B2.

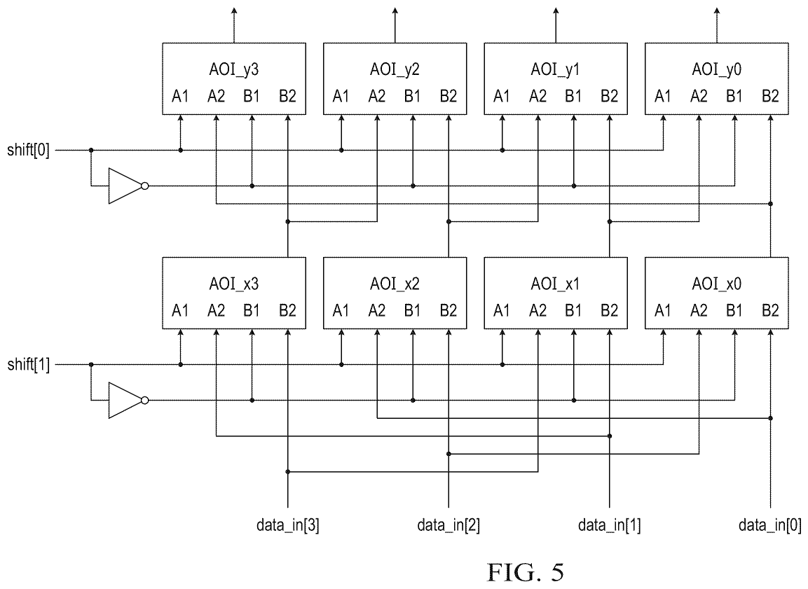

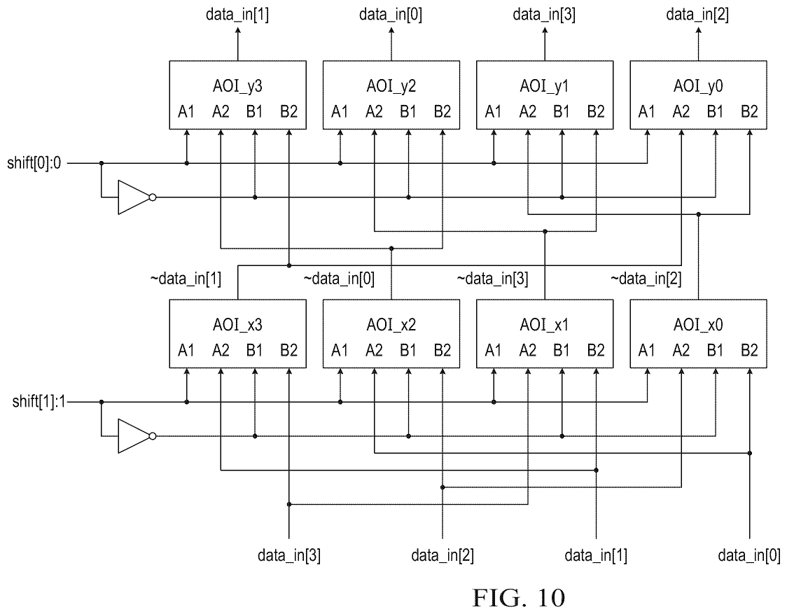

FIGS. 5 to 9 are schematic diagrams illustrating a shift circuit that is formed based on a plurality of AOI data selectors and is configured to shift data along a first direction according to examples of the present disclosure. FIG. 10 is a schematic diagram illustrating a shift circuit that is formed based on a plurality of AOI data selectors and is configured to shift data along a second direction according to examples of the present disclosure. The first direction may refer to shifting to the right, and the second direction may refer to shifting to the left.

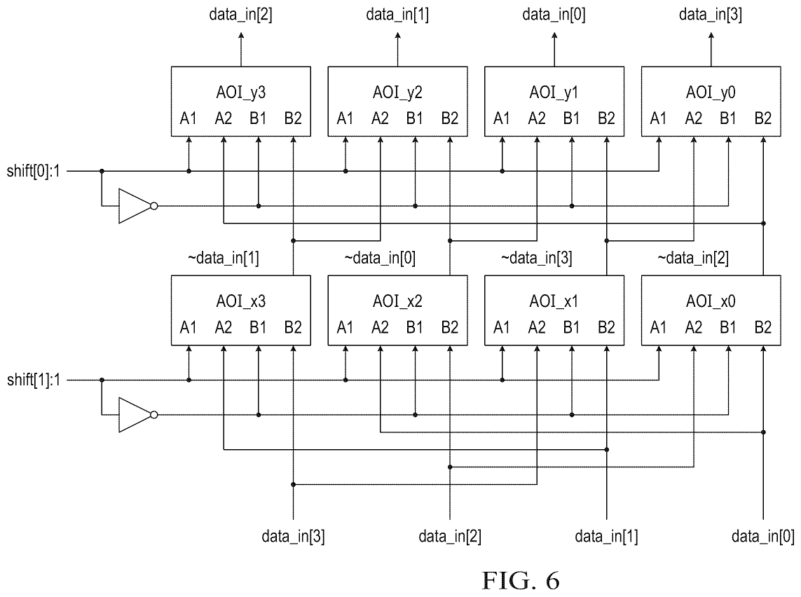

With reference to an example in FIG. 5, illustrating a schematic diagram of a shift circuit that comprises two levels of sub-shift circuits and performs a shift to the right, for example, each level of sub-shift circuit comprises 4 AOI data selectors. A shift bit width of each level of circuit is 1 bit, and each level of circuit may comprise 2 shift cases. One level of sub-shift circuit may correspond to a sub-shift circuit with a shift factor shift[1]. When shift[1] is 1, data is shifted to the right by 2¹ bits, and when shift[1] is 0, data is shifted by 0 bits. Another level of sub-shift circuit corresponds to a sub-shift circuit with a shift factor shift[0]. When shift[0] is 1, data is shifted to the right by 2⁰ bits, and when shift[0] is 0, data is shifted by 0 bits. The shift factor may be a mark for a high or low level of a control signal, and may be one of the control means for controlling the shift of the shift circuit, and is not one of the devices of the physical shift circuit. FIGS. 6 to 9 show examples of corresponding data outputs when various levels of sub-shift circuits are applied to shift data to the right when shift[1] and shift[0] respectively have different values.

The input bits to be shifted may comprise 4 bits, which are respectively data_in[3], data_in[2], data_in[1], and data_in[0]. Each corresponding level of sub-shift circuit comprises 4 AOI data selectors, and each level of sub-shift circuit may be separately used as one shift circuit. For example, if only 4 bits of data need to be shifted to the right by 2 bits, only the sub-shift circuit with the shift factor shift[1] is required, and the sub-shift circuit with the shift factor shift[0] may be omitted, or the shift factor shift[0] may be made to take 0 so that the sub-shift circuit shifts data by 0 bits. In some examples, input data may have more bits, and there are more levels of sub-shift circuits. A shift factor of a certain level of sub-shift circuit may be shift[i], when shift[i] is 1, the data is correspondingly shifted to the left by 2ⁱ bits or shifted to the right by 2ⁱ bits, and when shift[i] is 0, data is correspondingly shifted by 0 bits.

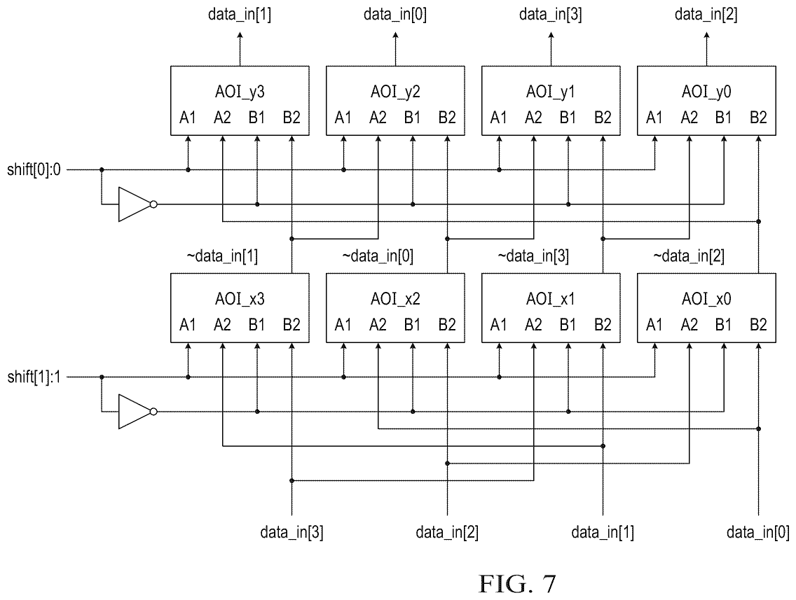

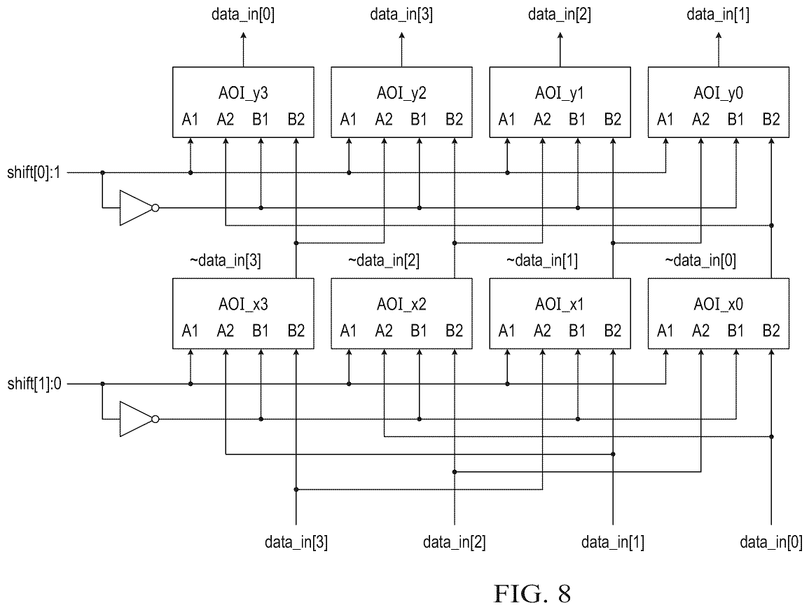

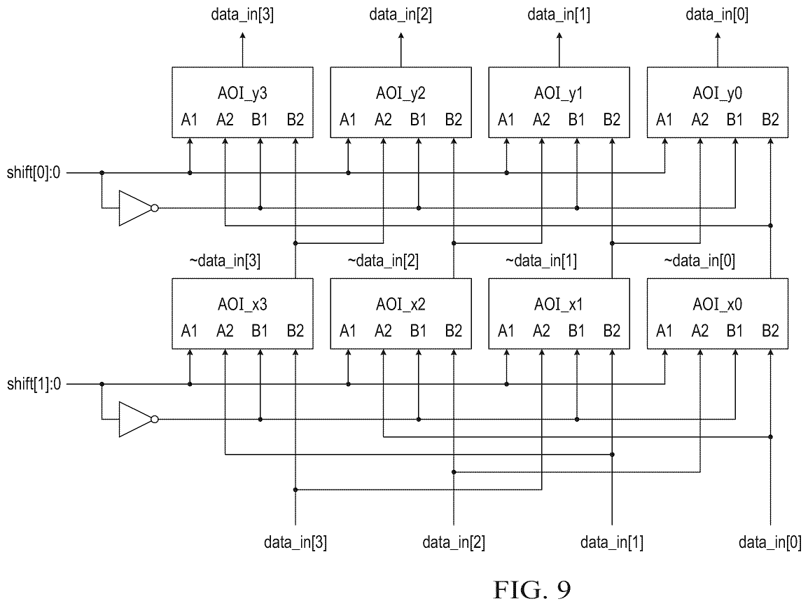

With reference to FIG. 5, taking a sub-shift circuit corresponding to the shift factor shift[1] and having data_in[3], data_in[2], data_in[1], and data_in[0] as inputs as an example. For data selectors AOI_x0, AOI_x1, AOI_x2, and AOI_x3, a first control signal is input at all terminals A1, a second control signal is input at all terminals B1, and an output signal of the inverter circuit may be received as the second control signal, such that the second control signal and the first control signal are inverse signals to each other. A signal to be selected is input at terminals A2 and terminals B2.data_in[0] is accessed at the terminal B2 of AOI_x0 and the terminal A2 of AOI_x2; data_in[1] is accessed at the terminal B2 of AOI_x1 and the terminal A2 of AOI_x3; data_in[2] is accessed at the terminal B2 of AOI_x2 and the terminal A2 of AOI_x0; and data_in[3] is accessed at the terminal B2 of AOI_x3 and the terminal A2 of AOI_x1. With reference to FIG. 6, the shift factor shift[1] is 1, each of the terminals A1 is configured to access the first control signal at a high level, and each of the terminals B1 is configured to access the second control signal at a low level. In this case, the first control signal is in a first state, and each of the output terminals A2 outputs an inverted value of data input at the terminal A2. AOI_x3, AOI_x2, AOI_x1, and AOI_x0 sequentially output ˜data_in[1], ˜data_in[0], ˜data_in[3], and ˜data_in[2], shifting the data to the right by 2 bits, and outputting inverted values. In other examples, the shift factor shift[1] is 0, each of the terminals A1 is configured to access the first control signal at a low level, and each of the terminals B1 is configured to access the second control signal at a high level. In this case, the first control signal is in a second state, and each of the output terminals B2 outputs an inverted value of data input at the terminal B2. AOI_x3, AOI_x2, AOI_x1, and AOI_x0 sequentially output ˜data_in[3], ˜data_in[2], ˜data_in[1], and ˜data_in[0], shifting the data by 0 bits, and outputting inverted values. FIGS. 6 and 7 illustrate a case when shift[1] is 1. For a case when shift[1] is 0, refer to a shift circuit illustrated in FIGS. 8 and 9 below.

With continued reference to FIG. 6, for a sub-shift circuit with a shift factor shift[1], a first bit and a second bit are only used for differentiating between different data in the input data accessed at the terminal B2 and the terminal A2 of the AOI data selector, do not refer to first data and second data, and do not refer to data_in[0] and data_in[1]. Taking the AOI_x0 as an example, the first bit is data_in[0], and the second bit is data_in[2], wherein the second bit refers to data to be output on the AOI_x0 by shifting original data. Similarly, the original data has an original arrangement before being input into the data selectors. For example, the arrangement is data_in[3], data_in[2], data_in[1], and data_in[0] in sequence from left to right in FIG. 6, and the arrangement of the AOI data selector is also AOI_x3, AOI_x2, AOI_x1, and AOI_x0 from left to right. Data is first input into the terminal B2 of each AOI data selector in a one-to-one correspondence from left to right. The sub-shift circuit shifts the data to the right by 2 bits. data_in[2] input from AOI_x2 should be shifted to the terminal A2 of AOI_x0 for output. In this case, the terminal A2 of AOI_x0 is also configured to access data_in[2]. When the first control signal is at a high level and is in the first state, an inverted value of data at the second input terminal A2 of AOI_x0 is output, that is, ˜data_in[2] is output. If the first control signal is at a low level and is in the second state, an inverted value of data at the terminal B2 of AOI_x0 is output, that is, ˜data_in[0] is output. In this case, the data is shifted by 0 bits. Still taking the AOI_x1 as an example, a first bit accessed at the terminal B2 of AOI_x1 is data_in[1], and a second bit accessed at the terminal A2 of AOI_x1 is data_in[3]. Details of other AOI data selectors are not described again.

In FIG. 6, the sub-shift circuit corresponding to the shift factor shift[1] outputs data to a sub-shift circuit corresponding to a shift factor shift[0], and the sub-shift circuit corresponding to shift[0] then outputs the data. AOI_x0 outputs ˜data_in[2], which is accessed at a terminal B2 of AOL_y0 and a terminal A2 of AOL_y3. AOI_x1 outputs ˜data_in[3], which is accessed at a terminal B2 of AOL_y1 and a terminal A2 of AOL_y0. AOI_x2 outputs ˜data_in[0], which is accessed at a terminal B2 of AOL_y2 and a terminal A2 of AOL_y1. AOI_x3 outputs ˜data_in[1], which is accessed at a terminal B2 of AOL_y3 and a terminal A2 of AOL_y2. In an example, for AOI_y0, a first bit accessed at the terminal B2 of AOL_y0 is ˜data_in[2], and a second bit accessed at the terminal A2 of AOI_y0 is ˜data_in[3]. For AOL_y1, a first bit accessed at the terminal B2 of AOL_y1 is ˜data_in[3], and a second bit accessed at the terminal A2 of AOL_y1 is ˜data_in[0]. The shift factor shift[0] is 1, each terminal A1 is configured to access the first control signal at a high level, and each terminal B1 is configured to access the second control signal at a low level. In this case, the first control signal is in a first state, and each output terminal outputs an inverted value of data input at the terminal A2. AOI_y3, AOI_y2, AOL_y1, and AOL_y0 output data_in[2], data_in[1], data_in[0], and data_in[3] in sequence, shifting the data to the right by 1 bit, and outputting inverted values. With reference to FIG. 7, output data of a corresponding sub-shift circuit when the shift factor shift[1] is 1 is the same as that of the corresponding sub-shift circuit when the shift factor shift[1] is 1 in FIG. 6. When the shift factor shift[0] is 0 in FIG. 7, each terminal A1 of the sub-shift circuit corresponding to shift[0] is configured to access the first control signal at a low level, and each terminal B1 is configured to access the second control signal at a high level. In this case, the first control signal is in the second state, and each output terminal outputs an inverted value of data input at the terminal B2. AOI_y3, AOL_y2, AOL_y1, and AOL_y0 output data_in[1], data_in[0], data_in[3], and data_in[2] in sequence, shifting the data by 0 bits, and outputting inverted values.

In some examples, the sub-shift circuit corresponding to the shift factor shift[1] shown in FIG. 6 may be used as a first level of circuit that receives original input data, or may be used as a last level of circuit or any level of circuit. The sub-shift circuit corresponding to the shift factor shift[0] may be used as a first level of circuit that receives original input data, or may be used as a last level of circuit or any level of circuit. A level that an example sub-shift circuit is at in an entire shift circuit is not limited in examples of the present disclosure.

In some examples, FIG. 8 illustrates a shift circuit that is formed based on a plurality of AOI data selectors and is configured to shift data to the right. In FIG. 8, the shift factor shift[1] is 0, and the sub-shift circuit corresponding thereto shifts the original input data data_in[3], data_in[2], data_in[1], and data_in[0] by 0 bits which is then inverted to output to the sub-shift circuit corresponding to the shift factor shift[0]. When the shift factor shift[0] is 1, received data is shifted to the right by 1 bit and then inverted to output data, and the output data is data_in[0], data_in[3], data_in[2], and data_in[1].

In some examples, FIG. 9 illustrates a shift circuit that is formed based on a plurality of AOI data selectors and is configured to shift data to the right. In FIG. 9, the shift factor shift[1] is 0, and the sub-shift circuit corresponding thereto shifts the original input data data_in[3], data_in[2], data_in[1], and data_in[0] by 0 bits which is then inverted to output to the sub-shift circuit corresponding to the shift factor shift[0]. When the shift factor shift[0] is 0, received data is shifted by 0 bit and then inverted to output data, and the output data is data_in[3], data_in[2], data_in[1], and data_in[0].

In some examples, FIG. 10 illustrates a shift circuit that is formed based on a plurality of AOI data selectors and is configured to shift data to the left. When the shift factor shift[1] is 1, the level of sub-shift circuit shifts input data to the left by 21 bits, and when shift[1] is 0, shifts the input data by 0 bits. When shift[0] is 1, the level of sub-shift circuit shifts data to the left by 2° bits, and when shift[0] is 0, shifts the data by 0 bits. FIG. 10 only illustrates cases when shift[1] is 1 and shift[0] is 0. For other cases, refer to the foregoing shift circuit configured to shift data to the right by analogy.

In FIG. 10, taking the sub-shift circuit corresponding to the shift factor shift[1] as an example. For data selectors AOI_x0, AOI_x1, AOI_x2, and AOI_x3, a first control signal is input at all terminals A1, a second control signal is input at all terminals B1, and an output signal of the inverter circuit may be received as the second control signal, such that the second control signal and the first control signal have opposite logic levels. A signal to be selected is input at terminals A2 and terminals B2.data_in[0] is accessed at the terminal B2 of AOI_x0 and the terminal A2 of AOI_x2; data_in[1] is accessed at the terminal B2 of AOI_x1 and the terminal A2 of AOI_x3; data_in[2] is accessed at the terminal B2 of AOI_x2 and the terminal A2 of AOI_x0; and data_in[3] is accessed at the terminal B2 of AOI_x3 and the terminal A2 of AOI_x1. The shift factor shift[1] is 1, each terminal A1 is configured to access the first control signal at a high level, and each terminal B1 is configured to access the second control signal at a low level. In this case, the first control signal is in a first state. Each output terminal outputs an inverted value of data input at the terminal A2. AOI_x3, AOI_x2, AOI_x1, and AOI_x0 output ˜data_in[1], ˜data_in[0], ˜data_in[3], and ˜data_in[2] in sequence, shifting the data to the left by 2 bits, and outputting inverted values. Taking the AOI_x0 as an example, the first bit is data_in[0], and the second bit is data_in[2], wherein the second bit refers to data to be output on AOI_x0 by shifting original data. Taking the AOI_x1 as an example, a first bit accessed at the terminal B2 of AOI_x1 is data_in[1], and a second bit accessed at the terminal A2 of AOI_x1 is data_in[3]. Details of other AOI data selectors are not described again.

In FIG. 10, for the sub-shift circuit corresponding to the shift factor shift[0], AOI_x0 outputs ˜data_in[2], which is accessed at a terminal B2 of AOI_y0 and a terminal A2 of AOL_y1. AOI_x1 outputs ˜data_in[3], which is accessed at a terminal B2 of AOL_y1 and a terminal A2 of AOI_y2. AOL_x2 outputs ˜data_in[0], which is accessed at a terminal B2 of AOL_y2 and a terminal A2 of AOL_y3. AOI_x3 outputs ˜data_in[1], which is accessed at a terminal B2 of AOL_y3 and a terminal A2 of AOL_y0. In an example, for AOI_y0, a first bit accessed at the terminal B2 of AOI_y0 is ˜data_in[2], and a second bit accessed at the terminal A2 of AOL_y0 is ˜data_in[1]. For AOL_y1, a first bit accessed at the terminal B2 of AOL_y1 is ˜data_in[3], and a second bit accessed at the terminal A2 of AOL_y1 is ˜data_in[2]. The shift factor shift[0] is 1, each terminal A1 is configured to access the first control signal at a high level, and each terminal B1 is configured to access the second control signal at a low level. In this case, the first control signal is in a first state. Each output terminal outputs an inverted value of data input at the terminal A2. AOL_y3, AOL_y2, AOL_y1, and AOI_y0 output data_in[1], data_in[0], data_in[3], and data_in[2] in sequence, shifting the data to the left by 1 bit, and outputting inverted values.

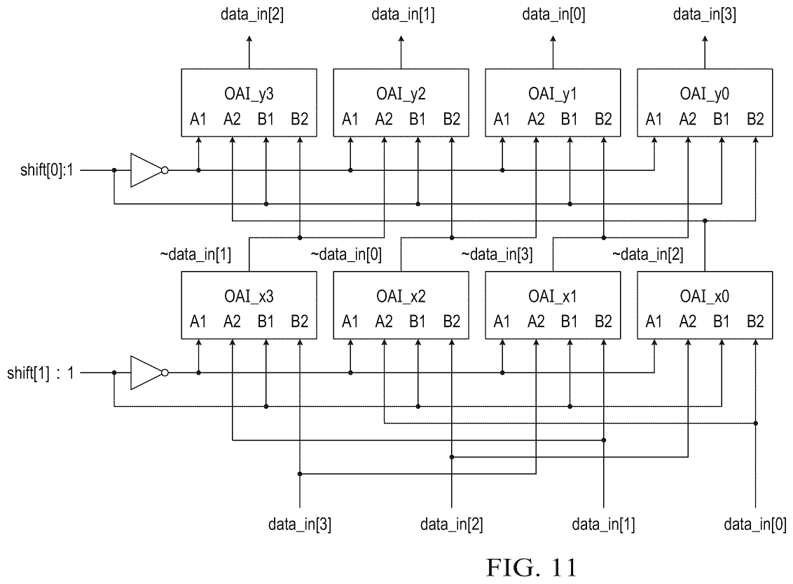

In some examples, a shift circuit configured to shift data to the left or shift data to the right may be built by using a plurality of OAI data selectors. For a single level of sub-shift circuit or a shift circuit that only comprises one level of circuit, bit widths of input data are same, and shift directions of data are same. When shift factors are same, signals to be selected accessed at a terminal A2 and a terminal B2 of the OAI data selector are the same as those of a shift circuit formed by AOI data selectors. For a shift circuit that is formed based on a plurality of OAI data selectors and is configured to shift data to the right as provided in FIG. 11, when a shift factor shift[1] is 1, the level of sub-shift circuit shifts input data to the right by 21 bits, and when shift[1] is 0, shifts input data by 0 bits. When shift[0] is 1, the level of sub-shift circuit shifts data to the right by 2° bits, and when shift[0] is 0, shifts data by 0 bits. FIG. 11 only illustrates cases when shift[1] is 1 and shift[0] is 0. Physical connections of a terminal A2 and a terminal B2 of an OAI data selector of a sub-shift circuit corresponding to the shift factor shift[1] in FIG. 11 may be the same as those of the AOI data selector of the sub-shift circuit corresponding to the shift factor shift[1] in FIG. 5. Physical connections of a terminal A2 and a terminal B2 of an OAI data selector of a sub-shift circuit corresponding to a shift factor shift[0] in FIG. 11 may be the same as those of the AOI data selector of the sub-shift circuit corresponding to the shift factor shift[0] in FIG. 5. When shift[1] in FIG. 11 is 1 and shift[0] is 1, data output and data input of each level of sub-shift circuits are the same as those in FIG. 6, but levels of first control signals are different. Taking the sub-shift circuit corresponding to shift[1] as an example. When shift[1] is 1, the first control signal accessed at the terminal A1 of the AOI data selector in FIG. 6 is at a high level, and the first control signal at a high level is in a first state. The first control signal accessed at the terminal A1 of the OAI data selector in FIG. 11 is at a low level, and the first control signal at a low level is in the first state. The OAI data selector and the AOI data selector in the first state both output inverted values of data input at the terminals A2. When shift[1] is 0, the first control signal accessed at the terminal A1 of the AOI data selector in FIG. 6 is at a low level, and the first control signal at a low level is in a second state. The first control signal accessed at the terminal A1 of the OAI data selector in FIG. 11 is at a high level, and the first control signal at a high level is in the second state. The OAI data selector and the AOI data selector in the second state both output inverted values of data input at the terminals B2.

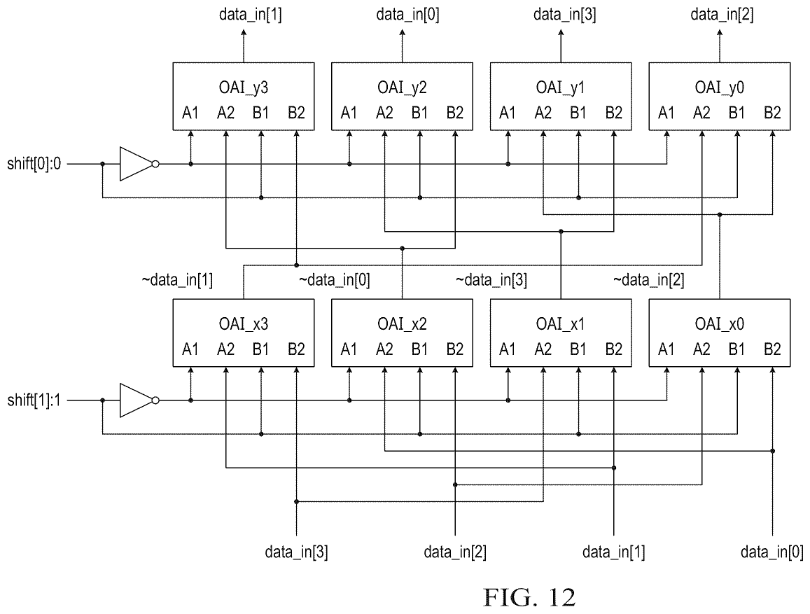

In some examples, FIG. 12 illustrates a shift circuit that is formed based on a plurality of OAI data selectors and is configured to shift data to the left. A data shift output case of the shift circuit is the same as that of the shift circuit that is formed by the AOI data selector in FIG. 10 and is configured to shift data to the left. A first control signal accessed at a terminal A1 of the OAI data selector in FIG. 12 is at a low level when in the first state, and the first control signal accessed at the terminal A1 of the AOI data selector in FIG. 10 is at a high level when in the first state.

For the shift circuit provided in the examples of the present disclosure, data output of the data selector may be controlled by controlling a high and low level of the first control signal, facilitating the realization of multiple shift scenarios of the input data through logic control, facilitating the expansion of the adaptability of the shift circuit to a variety of integrated circuits, while further reducing a circuit area of the shift circuit, which helps to improve a level of integration of the integrated circuits.

In a physical circuit, different levels of access of the first control signal can be achieved by arranging an inverter circuit to connect to the terminal A1 or the terminal B1. The inverter circuit may comprise an inverter.

In some examples, with reference to FIGS. 5 to 10, the shift circuit formed by the AOI data selector further comprises: an inverter circuit coupled with the third input terminal B1, wherein the first input terminal A1 and the inverter circuit are configured to access a high level, the first control signal at the high level is in the first state, and the third input terminal B1 is configured to access a low level output by the inverter circuit; or the first input terminal A1 and the inverter circuit are configured to access a low level, the first control signal at the low level is in the second state, and the third input terminal B1 is configured to access a high level output by the inverter circuit.

A control level is input into one level of sub-shift circuit, and is respectively input into the terminal A1 and an input terminal of the inverter circuit in a parallel manner. The control level is accessed at the terminal A1 as the first control signal, and the inverter circuit outputs an inverse signal of the control level which is accessed at the terminal B1 as the second control signal, such that logical levels of the second control signal and the first control signal are opposite. A high level and a low level of the control level may be controlled by shift factors corresponding to each level of sub-shift circuit. When shift[1] is 1 or shift[0] is 1, the control level is a high level input, and the terminal A1 of the AOI data selector receives the first control signal at a high level. In this case, the first control signal at a high level is in the first state, the terminal B1 receives the second control signal at a low level output by the inverter circuit, and the corresponding sub-shift circuit outputs an inverted value of data input at the terminal A2, achieving shift of data (shift of non-0 bits). When shift[1] is 0 or shift[0] is 0, the control level is a low level input, and the terminal A1 of the AOI data selector receives the first control signal at a low level. In this case, the first control signal is in the second state, the terminal B1 receives the second control signal at a high level output by the inverter circuit, and the corresponding sub-shift circuit outputs an inverted value of data input at the terminal B2, and data is not shifted (or shifted by 0 bits).

In some examples, with reference to FIGS. 11 and 12, the shift circuit formed by the OAI data selector further comprises: an inverter circuit coupled with the first input terminal A1, wherein the inverter circuit and the third input terminal B1 are configured to access a high level, the first input terminal A1 is configured to access a low level output by the inverter circuit, and the first control signal at the low level is in the first state; or the inverter circuit and the third input terminal B1 are configured to access a low level, the first input terminal A1 is configured to access a high level output by the inverter circuit, and the first control signal at the high level is in the second state.

A control level is input into one level of sub-shift circuit, and is respectively input into the B1 and an input terminal of the inverter circuit in a parallel manner. The control level is accessed at the terminal B1 as the second control signal, and the inverter circuit outputs an inverse signal of the control level which is accessed at the terminal A1 as the first control signal, such that logical levels of the first control signal and the second control signal are opposite. A high level and a low level of the control level may be controlled by shift factors corresponding to each level of sub-shift circuit. When shift[1] is 1 or shift[0] is 1, the control level is a high level input, and the terminal A1 of the OAI data selector receives the first control signal at a low level output by the inverter circuit. In this case, the first control signal at a low level is in the first state, the terminal B1 receives the second control signal at a high level, the corresponding sub-shift circuit outputs an inverted value of data input at the terminal A2, achieving shift of data (shift of non-0 bits). When shift[1] is 0 or shift[0] is 0, the control level is a low level input, and the terminal A1 of the OAI data selector receives the first control signal at a high level output by the inverter circuit. In this case, the first control signal at a high level is in the second state, the terminal B1 receives the second control signal at a low level, the corresponding sub-shift circuit outputs an inverted value of data input at the terminal B2, and data is not shifted (or shifted by 0 bits).

In some examples, the shift circuit comprises a plurality of data selectors, wherein the second input terminal A2 of the data selector is configured to access a corresponding second bit of the input data after being shifted by 2ⁱ bits, wherein i comprises any integer greater than or equal to 0.

In some examples, the shift circuit comprises: n levels of sub-shift circuits, wherein each of the sub-shift circuits comprises the plurality of data selectors and is configured to: receive the input data, and shift the input data by 2ⁱ bits, wherein the input data comprises output data of a previous level of sub-shift circuit or original input data, and a value of i of any level of sub-shift circuit of the n levels of sub-shift circuits comprises any integer from 0 to n−1, wherein a value of n comprises any integer greater than or equal to 1.

The shift circuit may comprise one level of circuit, or may comprise a plurality of levels of circuits. For example, as shown in FIG. 6, the shift circuit comprises a plurality of levels of sub-shift circuits formed by a plurality of AOI data selectors, and each level of the sub-shift circuits comprises a plurality of AOI data selectors. In some examples, one shift circuit may only comprise one level of sub-shift circuit shown in FIG. 6, for example, any level of sub-shift circuit corresponding to a shift factor shift[1] or a shift factor shift[0]. In some other examples, one shift circuit may comprise more levels of sub-shift circuits, for example, n levels of sub-shift circuits, wherein a shift factor corresponding to one level of sub-shift circuit may be shift[i], and a value of i comprises any integer from 0 to n−1. The n levels of sub-shift circuits correspond to n shift factors, and one level of sub-shift circuit shifts data by 2ⁱ bits and outputs an inverted value. The shift circuit may be any level of sub-shift circuit or a plurality of levels of sub-shift circuits in the above-mentioned n levels of sub-shift circuits. The shifting the data by 2ⁱ bits may be shifting the data to the right in FIG. 6 or may be shifting the data to the left in FIG. 10.

Still with reference to FIG. 6, input data of the shift factor shift[0] is data output from a sub-shift circuit that is of a previous level and corresponds to the shift factor shift[1]. The shift factor shift[1] may receive output data of the previous level of sub-shift circuit, or may be used as a first level of sub-shift circuit to receive the original input data.

For a shift circuit having n levels of sub-shift circuits, a first level of sub-shift circuit may be a 1st level of sub-shift circuit of the shift circuit that receives the original input data, a second level of sub-shift circuit receives output data of the first level of sub-shift circuit, and by analogy, an nth level of sub-shift circuit is a last level of sub-shift circuit that outputs data of the entire shift circuit. A sub-shift circuit corresponding to the shift factor shift[i] may be any level of sub-shift circuit of the n levels of circuit. For example, as shown in FIG. 6, a sub-shift circuit corresponding to the shift factor shift[1] may be the first level of circuit or may be any level of circuit, and the sub-shift circuit corresponding to a shift factor shift[0] may be a last level of circuit or may be any level of circuit.

In some examples, values of i in a first level of sub-shift circuit, a second level of sub-shift circuit, . . . , and an nth level of sub-shift circuit of the n levels of sub-shift circuits are respectively n−1, n−2, n−3, . . . , and 0, and a number of data selectors comprised in each level of sub-shift circuit is the same as a number of bits of the input data.

With reference to FIG. 6, the shift circuit may comprise 2 levels of sub-shift circuits, that is, n=2. A shift factor corresponding to the first level of sub-shift circuit is shift[i=2−1], and a shift factor corresponding to the second level of sub-shift circuit is shift[i=2−2]. An input data bit width corresponding to the shift circuit is 4 bits, the number of AOI data selectors corresponding to each level is 4, and the number of data selectors comprised in the entire shift circuit equals to a product of the input data bit width multiplied by the number of levels or the number of sub-shift circuits.

In some examples, the sub-shift circuit is configured to: receive the input data, and shift the input data by 2 bits under control of one bit in a shift factor, wherein a bit in the shift factor is to generate a first control signal and a second control signal for a corresponding level.

In the example, a data output of each level of sub-shift circuit may be controlled through a shift factor, to further control a data output of the shift circuit. For example, as shown in FIG. 6, two shift factors may be configured to select which level of shift factor is 1 or 0 using a control signal or a control setting. For example, shift[1:0] represents two shift factors, which are mapped to binary bits 2′bj₁j₀, wherein j₂ and j₁ may be used as bits for corresponding shift factors, and may be one of 0 and 1. In an example, in FIG. 6, when shift[1:0]=2′b11, shift[1]=1, and shift[0]=1. For a shift circuit formed by AOI data selectors, a first control signal of the level of sub-shift circuit is controlled to be at a high level, and a second control signal is controlled to be at a low level. In an example, in FIG. 7, shift[1:0]=2′b10, and shift[1]=1; and shift[0]=0. For a shift circuit formed by AOI data selectors, a first control signal of the level of sub-shift circuit is controlled to be at a high level, and a second control signal is controlled to be at a low level, shift[0]=0. For a shift circuit formed by AOI data selectors, a first control signal of the level of sub-shift circuit is controlled to be at a high level, and a second control signal is controlled to be at a high level. In some other examples, the shift circuit may comprise more levels of sub-shift circuits, wherein shift[(n−1):0] represents n shift factors, and shift[(n−1):0]=2′bjₙ₋₁, . . . , j₁, j₀.

In some examples, in a case that n is an even number, an output of a last level of sub-shift circuit of the n levels of sub-shift circuits is target data; and in a case that n is an odd number, an output of a last level of sub-shift circuit of the n levels of sub-shift circuits is inverted to obtain the target data.

For the AOI data selector or the OAI data selector in the shift circuit in the examples of the present disclosure, an inverted value of input data in a terminal A2 or a terminal B2 is output after a logical calculation. A sub-shift circuit at an odd-numbered level inverts the original input data for an odd number of times for output, and a sub-shift circuit at an even-numbered level inverts the original input data for an even number of times for output. In the example, data that is not inverted compared with the original input data may be defined as target data. Data output by the last level of sub-shift circuit at an even-numbered level is not inverted compared with the original input data, and is target data. Data output by the last level of sub-shift circuit at an odd-numbered level is inverted compared with the original input data, and an output value of the last level of sub-shift circuit at an odd-numbered level is inverted to obtain target data. The original input data is input to the first level of sub-shift circuit of the shift circuit.

In some examples, the number of the plurality of data selectors of the shift circuit is equal to the number of bits of the input data multiplied by the number of levels. A bit width of original data to be shifted may be denoted as m, and m bits of data is comprised, for example, data_in[0] to data_in[m]. One corresponding level of sub-shift circuit comprises m AOI data selectors or OAI data selectors, n levels of sub-shift circuits are disposed, and a total of m*n data selectors are required. A shift bit width of each level of sub-shift circuit is 1 bit, and may correspond to two cases of shifting data by 0 bits and shifting data by 2ⁱ bits. The shifting comprises a shift to the left or a shift to the right.

In an example, for data with a bit width of 256 bits and a shift with a shift bit width of 8 bits, 8 levels of sub-shift circuits are disposed, and a total of 256*8 AOI data selectors are required, which has a smaller circuit area compared with 256*8 data selectors MUX2_0 required for completing the same shift parameter and compared with 256*4 data selectors MUX4_0 required for completing the same shift parameter.

In some examples, for some same shift frequencies, the circuit area of the shift circuit formed by the AOI data selectors or the OAI data selectors has a smaller circuit area compared with a shift circuit formed by data selectors MUX2_0, and has a smaller area compared with a shift circuit formed by data selectors MUX4_0. In an example, for a frequency of 1200 MHZ-1400 MHz, the circuit area of the shift circuit formed by the AOI data selectors or the OAI data selectors is 20%-25% smaller compared with the circuit area of the shift circuit formed by the data selectors MUX4_0.

According to some aspects of examples of the present disclosure, a data selector is provided, comprising: a first input terminal A1, a second input terminal A2, a third input terminal B1, a fourth input terminal B2, and an output terminal, wherein the first input terminal A1 is configured to access a first control signal, the third input terminal B1 is configured to access a second control signal, the fourth input terminal B2 is configured to access a first bit, the second input terminal A2 is configured to input a second bit, the first control signal and the second control signal are inverse signals to each other, and when the first control signal is in a first state, the output terminal outputs an inverted value of the second bit; or when the first control signal is in a second state, the output terminal outputs an inverted value of the first bit.

The data selector comprises the AOI data selector shown in FIG. 2 or the OAI data selector shown in FIG. 3. With reference to FIG. 2, for the AOI data selector, a first control signal accessed at the terminal A1 is at a high level, a second control signal accessed at the terminal B1 is at a low level, and an output terminal outputs an inverted value of a second bit accessed at the terminal A2. The first control signal accessed at the terminal A1 is at a low level, the second control signal accessed at the terminal B1 is at a high level, and the output terminal outputs an inverted value of a first bit accessed at the terminal B2. With reference to FIG. 3, for the OAI data selector, a first control signal accessed at the terminal A1 is at a low level, a second control signal accessed at the terminal B1 is at a high level, and an output terminal outputs an inverted value of a second bit accessed at the terminal B2. The first control signal accessed at the terminal A1 is at a high level, the second control signal accessed at the terminal B1 is at a low level, and the output terminal outputs an inverted value of a first bit accessed at the terminal B2. The AOI data selector or the OAI data selector has a smaller circuit area compared with the data selector MUX2_0 and has a smaller circuit area compared with the data selector MUX4_0. Data output of the data selector may be controlled by controlling a high and low level of the first control signal, facilitating the realization of multiple shift scenarios of the input data through logic control, facilitating the expansion of the adaptability of the shift circuit to a variety of integrated circuits, and facilitating the expansion of the adaptability of the shift circuit to a variety of data shift algorithms.

According to some aspects of examples of the present disclosure, a memory system 100 is provided, comprising a memory device 104 and the memory controller 106, wherein the memory controller 106 is coupled with the memory device 104 and configured to control the memory device 104.

The data selector and the shift circuit provided in the examples of the present disclosure may be applied to integrated circuits that adapt to various data shifting algorithms, and may be applied in the memory controller 106. The memory controller 106 may be applied to the data selector or the shift circuit provided in this example to perform encoding operations, decoding operations, or other control operations. The encoding operation may be performed according to a low-density parity-check codes (LDPC) encoding rule.

The memory device in the examples of the present disclosure includes but is not limited to a three-dimensional NAND type memory, and for ease of understanding, a three-dimensional NAND type memory is used as an example for illustration.

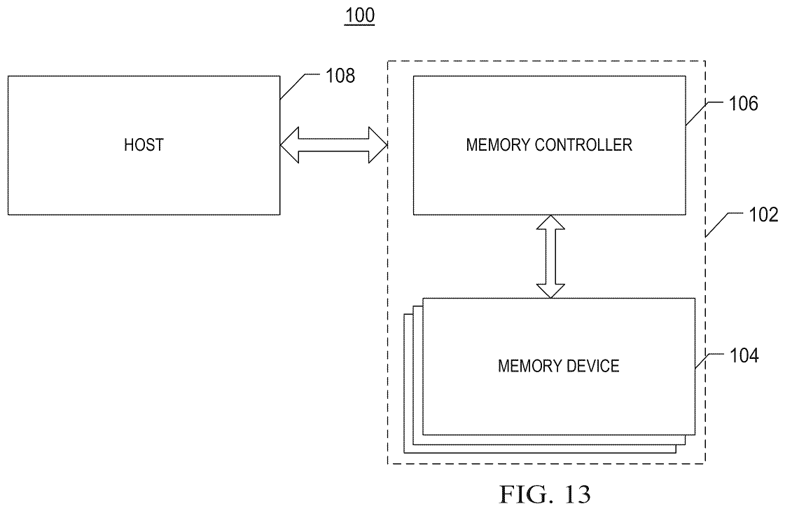

FIG. 13 illustrates a block diagram of an example system 100 having a memory device, according to some aspects of the present disclosure. System 100 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 13, system 100 can include a host 108 and a memory system 102 having one or more memory devices 104 and a memory controller 106. Host 108 can be a processor of an electronic device, such as a central processing unit (CPU), or a system-on-chip (SoC), such as an application processor (AP). Host 108 can be configured to send or receive data to or from the memory device 104.

Memory controller 106 is coupled to the memory device 104 and host 108 and is configured to control the memory device 104, according to some examples. Memory controller 106 can manage the data stored in memory device 104 and communicate with host 108. In some examples, memory controller 106 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some examples, memory controller 106 is designed for operating in a high duty-cycle environment SSD or embedded multi-media-cards (eMMC) used as data storage for mobile devices, such as smartphones, tablets, laptop computers, etc., and enterprise storage arrays.

Memory controller 106 can be configured to control operations of the memory device 104, such as read, erase, and program operations. Memory controller 106 can also be configured to manage various functions with respect to the data stored or to be stored in the memory device 104 including, but not limited to bad-block management, garbage collection, logical-to-physical address conversion, wear leveling, etc. In some examples, memory controller 106 is further configured to process error correction codes (ECC) with respect to the data read from or written to the memory device 104. Any other suitable functions may be performed by memory controller 106 as well, for example, formatting the memory device 104. Memory controller 106 can communicate with an external device (e.g., host 108) according to a particular communication protocol. For example, memory controller 106 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

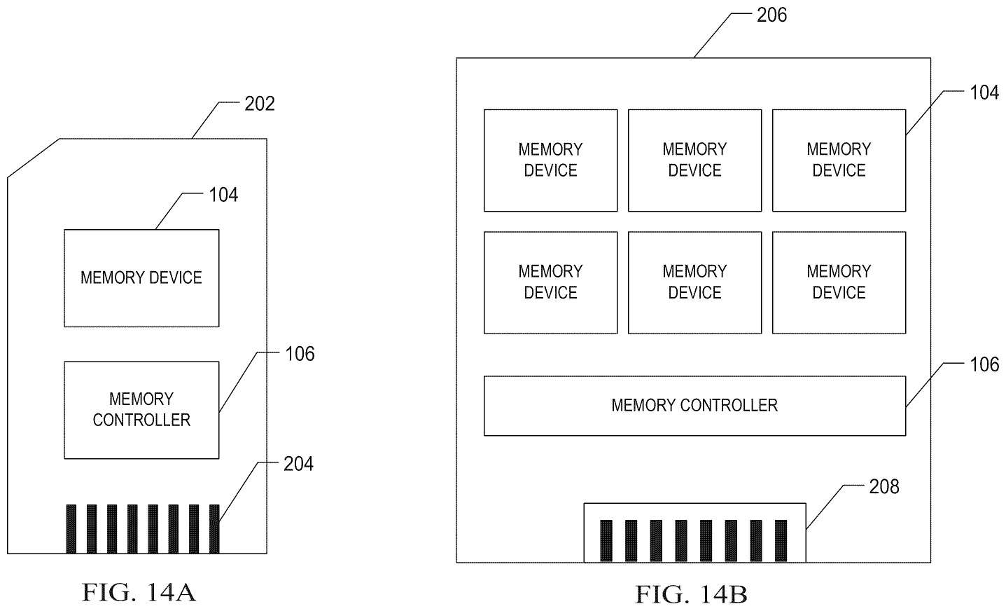

Memory controller 106 and one or more memory devices 104 can be integrated into various types of storage devices, for example, be included in the same package, such as a universal Flash storage (UFS) package or an eMMC package. That is, memory system 102 can be implemented and packaged into different types of end electronic products. In one example as shown in FIG. 14A, memory controller 106 and a single memory device 104 may be integrated into a memory card 202. Memory card 202 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 202 can further include a memory card connector 204 coupling the memory card 202 with a host (e.g., host 108 in FIG. 13). In another example as shown in FIG. 14B, the memory controller 106 and multiple memory devices 104 may be integrated into an SSD 206. SSD 206 can further include an SSD connector 208 coupling SSD 206 with a host (e.g., host 108 in FIG. 13). In some examples, at least one of the storage capacity or the operation speed of SSD 206 is greater than those of memory card 202.

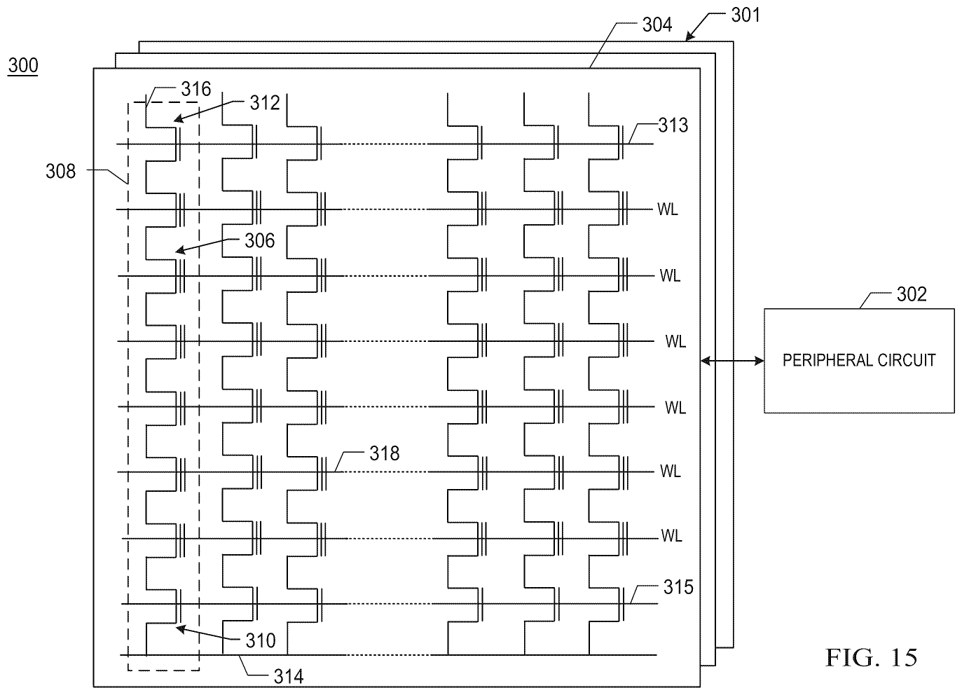

FIG. 15 illustrates a schematic circuit diagram of an example memory device 300 including peripheral circuits, according to some aspects of the present disclosure. The memory device 300 can be an example of the memory device 104 in FIG. 13. The memory device 300 can include a memory cell array 301 and peripheral circuits 302 coupled to memory cell array 301. The memory cell array 301 is illustrated as an example of a three-dimensional NAND type memory cell array, in which memory cells 306 are provided in the form of an array of NAND memory strings 308 each extending vertically above a substrate (not shown). In some examples, each NAND memory string 308 includes a plurality of memory cells 306 coupled in series and stacked vertically. Each memory cell 306 can hold a continuous, analog value, such as an electrical voltage or charge, that depends on the number of electrons trapped within a region of the memory cell 306. Each memory cell 306 can be either a floating gate type of memory cell including a floating-gate transistor or a charge trap type of memory cell including a charge-trap transistor.

In some examples, each memory cell 306 is a single-level cell (SLC) that has two possible memory states and thus, can store one bit of data. For example, the first memory state “0” can correspond to a first range of voltages, and the second memory state “1” can correspond to a second range of voltages. In some examples, each memory cell 306 is a multi-level cell (MLC) that is capable of storing more than a single bit of data in more than four memory states. For example, the MLC can store two bits per cell, three bits per cell (also known as Trinary-Level cell (TLC)), or four bits per cell (also known as a Quad-Level cell (QLC)). Each MLC can be programmed to assume a range of possible nominal storage values. In one example, if each MLC stores two bits of data, then the MLC can be programmed to write one of three possible nominal storage values to the cell. A fourth nominal storage value in addition to the three nominal storage values can be used to represent the erased state.

As shown in FIG. 15, each NAND memory string 308 can include a bottom selective gate 310 at its source end and a top selective gate 312 (TSG) at its drain end. BSG 310 and TSG 312 can be configured to activate selected NAND memory strings 308 during read and program operations. In some examples, the sources of NAND memory strings 308 in the same block 304 are coupled through the same source line (SL) 314, e.g., a common SL. In other words, all NAND memory strings 308 in the same block 304 have an array common source (ACS), according to some examples. TSG 312 of each NAND memory string 308 is coupled to a respective bit line (BL) 316 from which data can be read or written via an output bus (not shown), according to some examples. In some examples, each NAND memory string 308 is configured to be selected or deselected by at least one of: applying a select voltage (e.g., above the threshold voltage of the transistor having TSG 312) or a deselect voltage (e.g., 0 V) to respective TSG 312 through one or more TSG lines 313 or applying a select voltage (e.g., above the threshold voltage of the transistor having BSG 310) or a deselect voltage (e.g., 0 V) to respective BSG 310 through one or more BSG lines 315.

As shown in FIG. 15, the NAND memory strings 308 can be organized into multiple blocks 304, each of which can have a common source line 314, e.g., coupled to the ground. In some examples, each block 304 is the basic data unit for erase operations, i.e., all memory cells 306 on the same block 304 are erased at the same time. To erase memory cells 306 in a selected block 304a, source lines 314 coupled to selected block 304a as well as unselected blocks 304b in the same plane as selected block 304a can be biased with an erase voltage (Vers), such as a high positive voltage (e.g., 20 V or more). It is understood that in some examples, erase operation may be performed at a half-block level, a quarter-block level, or a level having any suitable number of blocks or any suitable fractions of a block. Memory cells 306 of adjacent NAND memory strings 308 can be coupled through word lines 318 that select which row of memory cells 306 is affected by read and program operations.

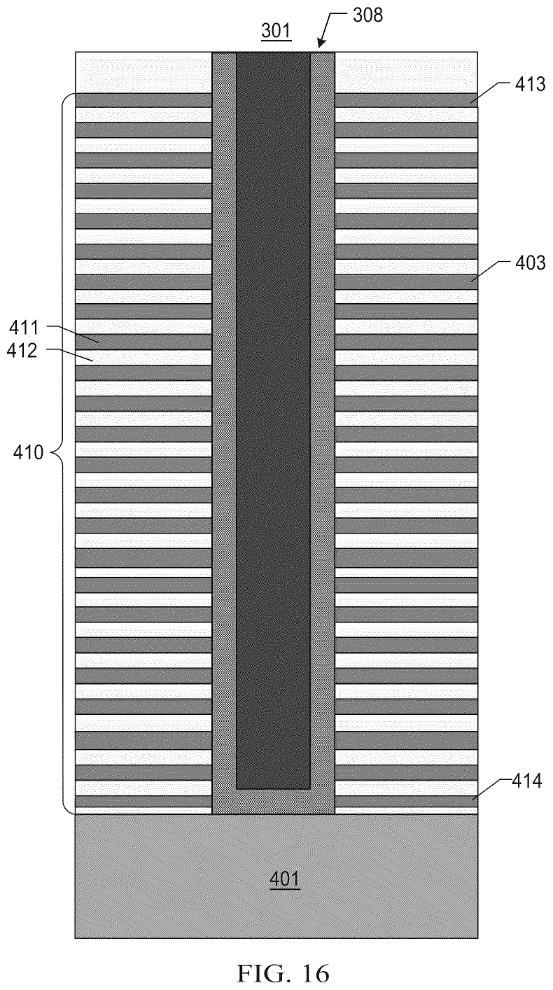

FIG. 16 shows a schematic cross-sectional view of an example memory cell array 301 including NAND memory strings 308 in accordance with aspects of the present disclosure. As shown in FIG. 16, the NAND memory strings 308 may include a stacked structure 410, which includes a plurality of gate layers 411 and a plurality of insulating layers 412 alternately stacked in sequence, and memory strings 308 penetrating vertically through the gate layers 411 and the insulating layers 412. The gate layer 411 and the insulating layer 412 can be stacked alternately, and two adjacent gate layers 411 are separated by an insulating layer 412. The number of pairs of gate layers 411 and insulating layers 412 in the stacked structure 410 may determine the number of memory cells included in the memory cell array 301.

The constituent material of the gate layer 411 may include a conductive material. The conductive material may include but is not limited to tungsten (W), cobalt (Co), Copper (Cu), aluminum (Al), polysilicon, doped silicon, silicide, or any combination thereof. In some examples, each gate layer 411 may include a metal layer, e.g., a tungsten layer. In some examples, each gate layer 411 includes a doped polysilicon layer. Each gate layer 411 may include a control gate surrounding the memory cell. The gate layer 411 at the top of the stacked structure 410 may extend laterally as a top selective gate line, the gate layer 411 at the bottom of the stacked structure 410 may extend laterally as a bottom selective gate line, and the gate layer 411 extending laterally between the top selective gate line and the bottom selective gate line may be used as a word line layer.

In some examples, the stacked structure 410 may be disposed on a substrate 401. The substrate 401 may include silicon (e.g., monocrystalline silicon), silicon germanium (SiGe), gallium arsenide (GaAs), germanium (Ge), silicon-on-insulator (SOI), germanium-on-insulator (GOI), or any other suitable material.

In some examples, the NAND memory string 308 includes a channel structure extending vertically through the stacked structure 410. In some examples, the channel structure includes a channel hole filled with semiconductor material(s) (e.g., as a semiconductor channel) and dielectric material(s) (e.g., as a memory film). In some examples, the semiconductor channel includes silicon, e.g., polysilicon. In some examples, the memory film is a composite dielectric layer including a tunneling layer, a storage layer (also referred to as a “charge trap/storage layer”), and a blocking layer. The channel structure may have a cylindrical shape (e.g., a pillar shape). According to some examples, the semiconductor channel, the tunneling layer, the storage layer and the blocking layer are radially arranged in this order from the center of the pillar toward the outer surface of the pillar. The tunneling layer may include silicon oxide, silicon oxynitride, or any combination thereof. The storage layer may include silicon nitride, silicon oxynitride, or any combination thereof. The blocking layer may include silicon oxide, silicon oxynitride, a high dielectric constant (high-k) dielectric, or any combination thereof. In one example, the memory film may include a composite layer of silicon oxide/silicon oxynitride/silicon oxide (ONO).

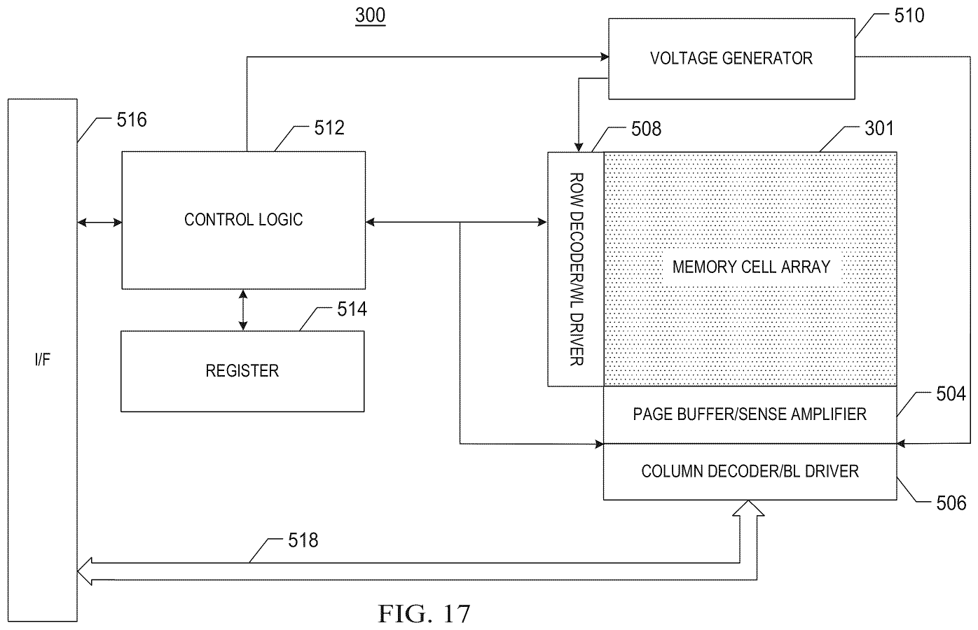

Referring back to FIG. 15, peripheral circuits 302 can be coupled to memory cell array 301 through bit lines 316, word lines 318, source lines 314, BSG lines 315, and TSG lines 313. Peripheral circuits 302 can include any suitable analog, digital, and mixed-signal circuits for facilitating the operations of memory cell array 301 by applying and sensing at least one of voltage signals or current signals to and from each target memory cell 306 through bit lines 316, word lines 318, source lines 314, BSG lines 315, and TSG lines 313. Peripheral circuits 302 can include various types of peripheral circuits formed using metal-oxide-semiconductor (MOS) technologies. For example, FIG. 17 illustrates some example peripheral circuits, the peripheral circuits 302 including a page buffer/sense amplifier 504, a column decoder/bit line driver 506, a row decoder/word line driver 508, a voltage generator 510, control logic 512, registers 514, an interface 516, and a data bus 518. It is understood that in some examples, additional peripheral circuits not shown in FIG. 17 may be included as well.

Page buffer/sense amplifier 504 can be configured to read and program (write) data from and to memory cell array 301 according to the control signals from control logic 512. In one example, page buffer/sense amplifier 504 may store program data (write data) to be programmed into memory cell array 301. In another example, page buffer/sense amplifier 504 may perform program verify operations to ensure that the data has been properly programmed into memory cells 306 coupled to selected word lines 318. In still another example, page buffer/sense amplifier 504 may also sense the low power signals from bit line 316 that represents a data bit stored in memory cell 306 and amplify the small voltage swing to recognizable logic levels in a read operation. Column decoder/bit line driver 506 can be configured to be controlled by control logic 512 and select one or more NAND memory strings 308 by applying bit line voltages generated from voltage generator 510.

Row decoder/word line driver 508 can be configured to be controlled by control logic 512 and select/deselect blocks 304 of memory cell array 301 and select/deselect word lines 318 of block 304. Row decoder/word line driver 508 can be further configured to drive word lines 318 using word line voltages generated from voltage generator 510. In some examples, row decoder/word line driver 508 can also select/deselect and drive BSG lines 315 and TSG lines 313 as well. As described below in detail, row decoder/word line driver 508 is configured to perform program operations on the memory cells 306 coupled to the selected word line(s) 318. Voltage generator 510 can be configured to be controlled by control logic 512 and generate the word line voltages (e.g., read voltage, program voltage, pass voltage, channel boost voltage, verification voltage, etc.), bit line voltages, and source line voltages to be supplied to memory cell array 301.

In some examples, the program operation may comprise a plurality of stages; in an example, the program operation may comprise a channel pre-charge stage, a channel boost stage, a program pulse stage and a recovery stage. In the channel pre-charge stage, the voltage generator may generate a voltage required in a next stage, such as a voltage applied to individual gates, the channel boost voltage, and the like. In the channel boost stage, the channel boost voltage may be applied to the selected word line. In the program pulse stage, a target voltage for each programming may be applied to the selected word line. In the recovery stage, operations may be performed on both the unselected and selected word lines, making the voltage decrease to a respective voltage such as Vcc and Vdd. The purpose of decreasing to the respective voltage may be achieved by one or more stepped voltage drops in the recovery stage, for example, the voltage may be decreased to an intermediate voltage first and held for a period of time at this intermediate voltage, and then decreased to the respective voltage.

Control logic 512 may be coupled to each peripheral circuit described above and configured to control the operation of each peripheral circuit. Registers 514 can be coupled to control logic 512 and include status registers, command registers, and address registers for storing status information, command operation codes (OP codes), and command addresses for controlling the operations of each peripheral circuit. Interface 516 may be coupled to control logic 512 and act as a control buffer to buffer and relay control commands received from a host (not shown) to control logic 512, and to buffer and relay status information received from control logic 512 to the host. Interface 516 may further be coupled to column decoder/bit line driver 506 via data bus 518 and act as a data I/O interface and data buffer to buffer and relay data to or from memory cell array 301.

In some examples, the memory cells of the NAND type memory may be divided into a single-level memory cell (a one-bit memory cell), a double-level memory cell (a two-bit memory cell), a triple-level memory cell (a three-bit memory cell), a quadra-level memory cell (a four-bit memory cell) and a penta-level memory cell (a five-bit memory cell) according to memory density. However, regardless of the single-level memory cell or the multi-level memory cell, the read operation thereof may be carried out in units of a page. In an example, when executing the read operation, a read voltage is applied to the word line (e.g., the selected word line) coupled to the selected page in the memory device 104, and when the read voltage reaches a threshold voltage of a plurality of memory cells coupled to the selected word line, or the number of the memory cells not reaching the threshold voltage is within an allowable range, the read operation for the entire page is concluded. The memory cell may be an M-bit memory cell and has 2^{M} memory states comprising the erased state, and M-bit memory data is read through a 2^{M-1} orders of read voltages. In an example, e.g., a first order of read voltage is between threshold voltages of the erased state and a first memory state, when the first order of read voltage is applied to the word line, the memory cell in the erased state is turned on, the memory cell in the first memory state is not turned on, and the erased state and the first memory state are distinguished and read out.

It is to be noted that during a process of performing the read operation, the memory cells not reaching the target threshold voltage is labeled as an error bit. In order to prevent the occurrence of a read error, an Error Correction Code (ECC) is introduced, all the error bits occurred in the read operation can be corrected when the number of the error bits is less than or equal to a maximum number of failure bits which can be corrected through the error correction code, and thus the correct read of the data may be achieved.

In some examples, the host 108 sends a read command (or a read instruction, a read request) to the memory controller 106 according to a current user command requirement; the memory controller 106 transmits a read control command including information such as a logical address-physical address mapping table to the memory device 104 through an interface 516, to control the memory device 104 to perform the read operation on the memory cell corresponding to the respective physical address. The memory device 104, in turn, sends the read data to the memory controller 106 through the interface 516, and the memory controller 106 feeds the data back to the host 108 via interfaces such as PCIe or SATA and the like. In an example, the memory controller 106 sends the read control command to the control logic of the memory device via the interface 516, and the control logic applies a related operation voltage to the selected word line or bit line according to the related physical address, so as to perform the read operation on the corresponding memory cell. A voltage generator may be controlled by the control logic to generate the related operation voltage according to the related read voltage mapping table, and the related operation voltage is decoded by the row decoder and applied to the word line of the respective address, or decoded by the column decoder and applied to the bit line of the respective address.

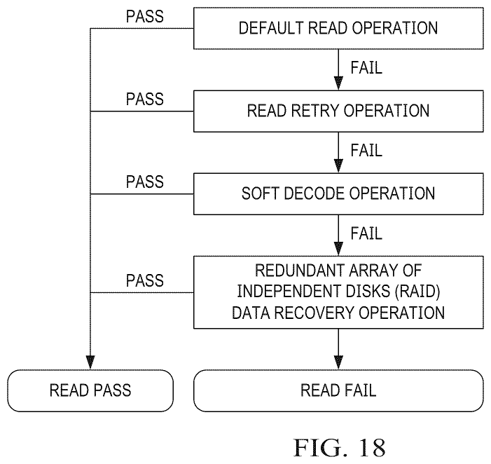

In some other examples, when the memory device 104 reads the respective memory cell under the control of the memory controller 106, a read error occurs; at this time, the respective read operation of the memory controller 106 fails; the memory (or, the error correction module in the memory controller 106) is controlled; and an error correction mode may comprise an ECC error correction. According to some aspects of examples of the present disclosure, FIG. 18 illustrates a flow diagram of an example read operation of a memory system 102. In conjunction with what is shown in FIG. 18, when the memory controller 106 controls the memory device 104 to perform the read operation, an FW default read operation is performed on the memory cell of the respective physical address first; a read retry operation is performed after the FW default read operation fails; a soft decode operation is performed after the read retry operation fails; an Redundant Array of Independent Disks (RAID) data recovery operation is performed after the soft decode operation fails; the read operation stops after the RAID data recovery operation fails since that the read fails due to incapability of error correction; and the memory controller 106 sends a read fail signal to the host 108. The read retry operation and the FW default read operation may be applied to hard decode.

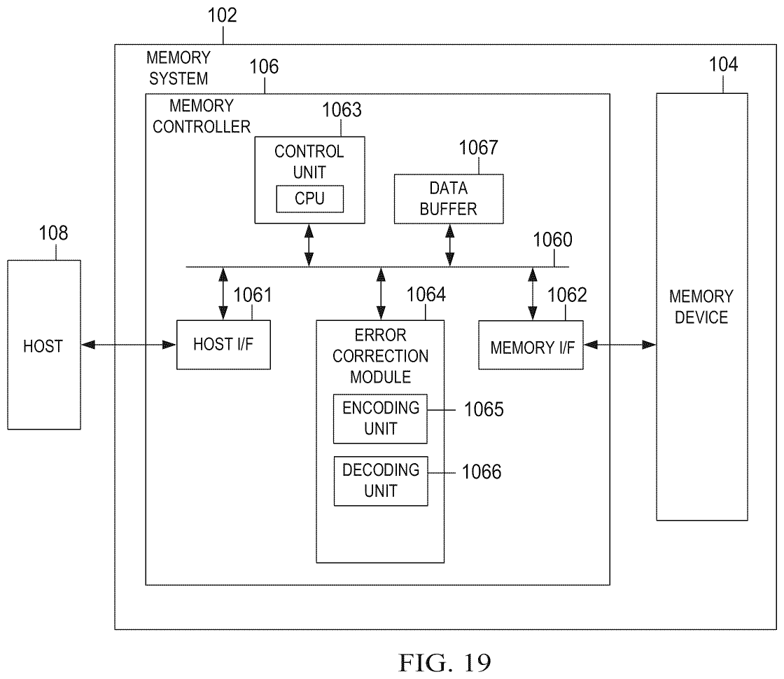

The error correction module 1064 (e.g., the ECC module) in the memory controller 106 may control the memory device 104 to perform the read retry, soft decode, RAID and other error correction operations; the control command is sent by the memory controller 106 to the memory device 104 via the interface 516; and the memory device 104 feeds read information back to the memory controller 106 via the interface 516. It is to be noted that the performance of subsequent operations may be stopped after any one of the read retry, the soft decode and the RAID succeeds. It is to be noted that FIG. 18 only illustrates a flow example of a read operation. In some other examples, the memory controller 106 may control the memory device 104 to perform the read retry operation, the soft decode and the RAID operation in any order, and no limitation is imposed by the present disclosure on a performance order. According to some aspects of examples of the present disclosure, FIG. 19 provides a block diagram of a memory system 102 comprising a memory controller 106 comprising an error correction module 1064. Referring to what is shown in FIG. 19, the memory system 102 comprises a memory controller 106 and a memory, wherein the memory controller 106 and the memory device 104 may be coupled in any suitable way. In examples of the present disclosure, the memory controller 106 comprises a host I/F 1061, a memory I/F 1062, a control unit 1063, an error correction (ECC) module 1064, a data buffer 1067 and an internal bus 1060, wherein the error correction module 1064 comprises an encoding unit 1065 and a decoding unit 1066. The host I/F 1061 outputs a command and user data (write data), and the like received from the host 108 to the internal bus 1060, and sends user data (read data) read from the memory device 104, and response from the control unit 1063 and the like to the host 108.

The memory I/F controls the process of writing user data and the like to the memory device 104 and the process of reading from the memory device 104 based on instructions from the control unit 1063. The control unit 1063 controls the memory system 102 as a whole. The control unit 1063 is, for example, a central processing unit (CPU), a microprocessor (MPU), or the like. When receiving a command from the host 108 via the host I/F 1061, the control unit 1063 performs control based on the command. For example, the control unit 1063 instructs the memory I/F to write user data and parity check data into the memory device 104 based on a command from the host 108. In addition, the control unit 1063 instructs the memory I/F to read user data and parity check data from the memory device 104 based on a command from the host 108.

The error correction module 1064 includes an encoding unit 1065 and a decoding unit 1066. The encoding unit 1065 encodes user data of a predetermined size written on the same page to generate parity check data. The parity check data is written in the page where the user data that is the basis for coding has been written, and the decoding unit 1066 uses the parity check data for decoding. The data buffer 1067 temporarily stores user data received from the host 108 before storing the user data in the memory device 104, and temporarily stores data read from the memory device 104 before sending the data to the host 108. The encoding unit 1065 comprises an encoding circuit for encoding, and the decoding unit 1066 comprises a decoding circuit for decoding.

In some particular examples, the soft decode operation may be understood as performing data re-decoding through the decoding unit (e.g., a soft decoder) in the memory controller 106, and performing the read operation again according to re-decoded data. The RAID operation may be understood as achieving data mirroring through secondary encoding to rebuild the storage data and the parity check data thereof, wherein re-encoding of a redundant array for the storage data is usually performed in the data buffer of the memory controller 106.

According to some aspects of examples of the present disclosure, with reference to FIG. 13, a memory controller 106 is provided. The memory controller 106 is configured to perform an encoding operation according to program data in response to a program operation to generate a check code. The memory controller 106 may comprise the shift circuit shown in FIGS. 5 to 12. The shift circuit comprises a data selector, wherein the data selector may comprise an AOI data selector or an OAI data selector. The data selector comprises a first input terminal A1, a second input terminal A2, a third input terminal B1, a fourth input terminal B2, and an output terminal, wherein the first input terminal A1 is configured to access a first control signal, the third input terminal B1 is configured to access a second control signal, the first control signal and the second control signal are inverse signals to each other, the fourth input terminal B2 is configured to access a corresponding first bit in input data, and the second input terminal A2 is configured to access a corresponding second bit in the input data, and when the first control signal is in a first state, the output terminal outputs an inverted value of the second bit; or when the first control signal is in a second state, the output terminal outputs an inverted value of the first bit, and wherein the shift circuit is configured to output the inverted value of the second bit or the inverted value of the first bit in response to the encoding operation.

In some examples, the memory controller 106 is further configured to: perform a decoding operation according to the corresponding check code in response to a read error to readout data, wherein the shift circuit is configured to output the inverted value of the second bit or the inverted value of the first bit in response to the decoding operation.

The memory controller 106 may comprise the encoding unit 1065 and the decoding unit 1066 shown in FIG. 19. The encoding unit 1065 and/or the decoding unit 1066 comprises the shift circuit in the examples of the present disclosure. The shift circuit may be located in another device of the memory controller 106. This is not limited in the examples of the present disclosure. When the encoding unit 1065 performs an encoding operation to generate a check code, the shift circuit is configured to perform a shift operation on input data in response to an encoding operation requirement. Each level of sub-shift circuits controls data outputs of each level of sub-shift circuits according to an encoding operation requirement and a shift factor being 1 or 0, and data corresponding to a plurality of shifting cases is output, thus adapting to a shift requirement of an encoding operation. The check code may comprise parity check data, or a check code generated according to another encoding rule.

When a read error occurs, the shift circuit is configured to perform a shift operation on input data in response to a decoding operation requirement. Each level of sub-shift circuits controls data outputs of each level of sub-shift circuits according to an encoding operation requirement and a shift factor being 1 or 0, and data corresponding to a plurality of shifting cases is output, thus adapting to a shift requirement of an encoding operation, to decode the check code to acquire erroneous data. The decoding operation may comprise hard decode, soft decode, and RAID decode.

In some examples, the shift circuit comprises a plurality of data selectors, and the second input terminal A2 of the data selector is configured to access a corresponding second bit of the input data after being shifted by 2ⁱ bits, wherein i comprises any integer greater than or equal to 0.

In some examples, the shift circuit comprises: n levels of sub-shift circuits, wherein each of the sub-shift circuits comprises the plurality of data selectors and is configured to: receive the input data, and shift the input data by 2ⁱ bits, wherein the input data comprises output data of a previous level of sub-shift circuit or original input data, and a value of i of any level of sub-shift circuit of the n levels of sub-shift circuits comprises any integer from 0 to n−1, wherein a value of n comprises any integer greater than or equal to 1.

In some examples, the sub-shift circuit is configured to: receive the input data, and shift the input data by 2ⁱ bits under control of one bit in a shift factor, wherein a bit in the shift factor is to generate a first control signal and a second control signal for a corresponding level.

In some examples, in a case that n is an even number, an output of a last level of sub-shift circuit of the n levels of sub-shift circuits is target data; and in a case that n is an odd number, an output of a last level of sub-shift circuit of the n levels of sub-shift circuits is inverted to obtain the target data.

In some examples, values of i in a first level of sub-shift circuit, a second level of sub-shift circuit, . . . , and an nth level of sub-shift circuit of the n levels of sub-shift circuits are respectively n−1, n−2, n−3, . . . , and 0, and the number of data selectors comprised in each level of sub-shift circuit is the same as the number of bits of the input data.

In some examples, the number of the plurality of data selectors of the shift circuit is equal to the number of bits of the input data multiplied by the number of levels.

In some examples, the shift circuit further comprises an inverter circuit coupled with the third input terminal B1, wherein the first input terminal A1 and the inverter circuit are configured to access a high level, the first control signal at the high level is in the first state, and the third input terminal B1 is configured to access a low level output by the inverter circuit; or
the first input terminal A1 and the inverter circuit are configured to access a low level, the first control signal at the low level is in the second state, and the third input terminal B1 is configured to access a high level output by the inverter circuit.

In some examples, the shift circuit further comprises an inverter circuit coupled with the first input terminal A1, wherein the inverter circuit and the third input terminal B1 are configured to access a high level, the first input terminal A1 is configured to access a low level output by the inverter circuit, and the first control signal at the low level is in the first state; or
the inverter circuit and the third input terminal B1 are configured to access a low level, the first input terminal A1 is configured to access a high level output by the inverter circuit, and the first control signal at the high level is in the second state.

The above descriptions are merely examples of the present disclosure, and the protection scope of the present disclosure is not limited to these. Any variation or substitution that may be readily contemplated by those skilled in the art within the technical scope disclosed by the present disclosure shall fall within the protection scope of the present disclosure. Therefore, the protection scope of the present disclosure shall be defined by the protection scope of the claims.

What is claimed is:

1. A shift circuit, comprising:
a data selector, comprising: a first input terminal, a second input terminal, a third input terminal, a fourth input terminal, and an output terminal, wherein
the first input terminal is configured to access a first control signal, the third input terminal is configured to access a second control signal, and the first control signal and the second control signal are inverse signals to each other,
the fourth input terminal is configured to access a first bit in input data,
the second input terminal is configured to access a second bit in the input data;
when the first control signal is in a first state, the output terminal outputs an inverted value of the second bit; and
when the first control signal is in a second state, the output terminal outputs an inverted value of the first bit.

2. The shift circuit of claim 1, comprising a plurality of data selectors, wherein the second input terminal of the data selector is configured to access a corresponding second bit of the input data after being shifted by 2ⁱ bits, wherein i comprises any integer greater than or equal to 0.

3. The shift circuit of claim 2, comprising:
n levels of sub-shift circuits, wherein each of the sub-shift circuits comprises the plurality of data selectors and is configured to: receive the input data, and shift the input data by 2ⁱ bits, wherein the input data comprises output data of a previous level of sub-shift circuit or original input data, and a value of i of any level of sub-shift circuit of the n levels of sub-shift circuits comprises any integer from 0 to n−1, wherein a value of n comprises any integer greater than or equal to 1.

4. The shift circuit of claim 3, wherein the sub-shift circuit is configured to:
receive the input data, and shift the input data by 2ⁱ bits under control of one bit in a shift factor, wherein a bit in the shift factor is to generate a first control signal and a second control signal for a corresponding level.

5. The shift circuit of claim 3, wherein
in a case that n is an even number, an output of a last level of sub-shift circuit of the n levels of sub-shift circuits is target data; and
in a case that n is an odd number, an output of a last level of sub-shift circuit of the n levels of sub-shift circuits is inverted to obtain the target data.

6. The shift circuit of claim 3, wherein values of i in a first level of sub-shift circuit, a second level of sub-shift circuit, . . . , and an nth level of sub-shift circuit of the n levels of sub-shift circuits are respectively n−1, n−2, n−3, . . . , and 0, and a number of data selectors comprised in each level of sub-shift circuit is the same as a number of bits of the input data.

7. The shift circuit of claim 3, wherein a number of the plurality of data selectors of the shift circuit is equal to a number of bits of the input data multiplied by a number of levels.

8. The shift circuit of claim 1, further comprising an inverter circuit coupled with the third input terminal, wherein
the first input terminal and the inverter circuit are configured to access a high level, the first control signal at the high level is in the first state, and the third input terminal is configured to access a low level output by the inverter circuit; or
the first input terminal and the inverter circuit are configured to access a low level, the first control signal at the low level is in the second state, and the third input terminal is configured to access a high level output by the inverter circuit.

9. The shift circuit of claim 1, further comprising an inverter circuit coupled with the first input terminal, wherein
the inverter circuit and the third input terminal are configured to access a high level, the first input terminal is configured to access a low level output by the inverter circuit, and the first control signal at the low level is in the first state; or
the inverter circuit and the third input terminal are configured to access a low level, the first input terminal is configured to access a high level output by the inverter circuit, and the first control signal at the high level is in the second state.

10. A memory controller, wherein the memory controller is configured to perform an encoding operation according to program data in response to a program operation to generate a check code and comprises a shift circuit, wherein the shift circuit comprises:
a data selector, comprising a first input terminal, a second input terminal, a third input terminal, a fourth input terminal, and an output terminal, wherein the first input terminal is configured to access a first control signal, the third input terminal is configured to access a second control signal, the first control signal and the second control signal are inverse signals to each other, the fourth input terminal is configured to access a first bit in input data, and the second input terminal is configured to access a second bit in the input data, and
when the first control signal is in a first state, the output terminal outputs an inverted value of the second bit; and
when the first control signal is in a second state, the output terminal outputs an inverted value of the first bit;
wherein the shift circuit is configured to output the inverted value of the second bit or the inverted value of the first bit in response to the encoding operation.

11. The memory controller of claim 10, further configured to:
perform a decoding operation according to the check code in response to a read error to readout data, wherein the shift circuit is configured to output the inverted value of the second bit or the inverted value of the first bit in response to the decoding operation.

12. The memory controller of claim 10, wherein the shift circuit comprises a plurality of data selectors, and the second input terminal of the data selector is configured to access a corresponding second bit of a shift of 2ⁱ bits of the input data, wherein i comprises any integer greater than or equal to 0.

13. The memory controller of claim 12, wherein the shift circuit comprises:
n levels of sub-shift circuits, wherein each of the sub-shift circuits comprises the plurality of data selectors and is configured to: receive the input data, and shift the input data by 2ⁱ bits, wherein the input data comprises output data of a previous level of sub-shift circuit or original input data, and a value of i of any level of sub-shift circuit of the n levels of sub-shift circuits comprises any integer from 0 to n−1, wherein a value of n comprises any integer greater than or equal to 1.

14. The memory controller of claim 13, wherein the sub-shift circuit is configured to:
receive the input data, and shift the input data by 2 bits under control of one bit in a shift factor, wherein a bit in the shift factor is to generate a first control signal and a second control signal for a corresponding level.

15. The memory controller of claim 13, wherein
in a case that n is an even number, an output of a last level of sub-shift circuit of the n levels of sub-shift circuits is target data; and
in a case that n is an odd number, an output of a last level of sub-shift circuit of the n levels of sub-shift circuits is inverted to obtain the target data.

16. The memory controller of claim 13, wherein values of i in a first level of sub-shift circuit, a second level of sub-shift circuit, . . . , and an nth level of sub-shift circuit of the n levels of sub-shift circuits are respectively n−1, n−2, n−3, . . . , and 0, and a number of data selectors comprised in each level of sub-shift circuit is the same as the number of bits of the input data.

17. The memory controller of claim 13, wherein a number of the plurality of data selectors of the shift circuit is equal to a number of bits of the input data multiplied by a number of levels.

18. The memory controller of claim 10, wherein the shift circuit further comprises an inverter circuit coupled with the third input terminal, wherein
the first input terminal and the inverter circuit are configured to access a high level, the first control signal at the high level is in the first state, and the third input terminal is configured to access a low level output by the inverter circuit; or
the first input terminal and the inverter circuit are configured to access a low level, the first control signal at the low level is in the second state, and the third input terminal is configured to access a high level output by the inverter circuit.

19. The memory controller of claim 10, wherein the shift circuit further comprises an inverter circuit coupled with the first input terminal, wherein
the inverter circuit and the third input terminal are configured to access a high level, the first input terminal is configured to access a low level output by the inverter circuit, and the first control signal at the low level is in the first state; or
the inverter circuit and the third input terminal are configured to access a low level, the first input terminal is configured to access a high level output by the inverter circuit, and the first control signal at the high level is in the second state.

20. A memory system, comprising:
a memory device; and
a memory controller coupled with the memory device and configured to control the memory device, wherein the memory controller is configured to perform an encoding operation according to program data in response to a program operation to generate a check code and comprises a shift circuit, wherein the shift circuit comprises:
a data selector, comprising a first input terminal, a second input terminal, a third input terminal, a fourth input terminal, and an output terminal, wherein the first input terminal is configured to access a first control signal, the third input terminal is configured to access a second control signal, the first control signal and the second control signal are inverse signals to each other, the fourth input terminal is configured to access a corresponding first bit in input data, and the second input terminal is configured to access a corresponding second bit in the input data, and
when the first control signal is in a first state, the output terminal outputs an inverted value of the second bit; and
when the first control signal is in a second state, the output terminal outputs an inverted value of the first bit;
wherein the shift circuit is configured to output the inverted value of the second bit or the inverted value of the first bit in response to the encoding operation.
